(19) United States
(12) Patent Application Publication
(10) Pub. No.: US 2026/0271272 A1
(43) Pub. Date: Sep. 10, 2026

(54) SEMICONDUCTOR DEVICE AND METHOD FOR FABRICATING THE SAME

(71) Applicant: SK hynix Inc., Gyeonggi-do (KR)

(72) Inventor: Yoon Jae NAM, Gyeonggi-do (KR)

(21) Appl. No.: 19/317,173

(22) Filed: Sep. 3, 2025

(30) Foreign Application Priority Data
Mar. 7, 2025 (KR) 10-2025-0029465

(51) Int. Cl. H10B 12/00

(52) U.S. Cl. CPC H10B 12/34; H10B 12/053

(57) ABSTRACT

Disclosed are a semiconductor device capable of increasing the upper area of an active region, and a method for fabricating the semiconductor device. The semiconductor device includes: a substrate including an isolation layer and a plurality of active regions that are defined by the isolation layer; a trench disposed in the substrate to cross the isolation layer and the plurality of active regions in a first direction; a semiconductor layer disposed on inner sidewalls and a bottom surface of the trench in each of the plurality of active regions; a buried gate structure disposed in the trench including the semiconductor layer.

### CROSS-REFERENCE TO RELATED APPLICATIONS

The present application claims priority under 35 U.S.C 119(a) to Korean Patent Application No. 10-2025-0029465, filed on Mar. 7, 2025, which is incorporated herein by reference in its entirety.

### BACKGROUND

### 1. Field

Embodiments of the present disclosure relate to a semiconductor device including a buried gate and a method for fabricating the same, and more particularly, to a semiconductor device with an increased contact area, and a method for fabricating the semiconductor device.

### 2. Description of the Related Art

As semiconductor devices become smaller and more highly integrated, diverse methods for forming fine patterns are being developed. Exposure equipment is being developed to form fine patterns for a general photolithography process. However, there are limitations in forming patterns whose line widths are equal to or smaller than a predetermined critical dimension.

Also, as semiconductor devices become smaller and smaller, it becomes difficult to secure a contact area for coupling an upper structure and a lower structure.

### SUMMARY

Embodiments of the present disclosure are directed to a semiconductor device capable of increasing the upper area of an active region, and a method for fabricating the semiconductor device.

In accordance with an embodiment of the present disclosure, a semiconductor device includes: a substrate including an isolation layer and a plurality of active regions that are defined by the isolation layer; a trench disposed in the substrate to cross the isolation layer and the plurality of active regions in a first direction; a semiconductor layer disposed on inner sidewalls and a bottom surface of the trench in each of the plurality of active regions; a buried gate structure disposed in the trench including the semiconductor layer.

In accordance with another embodiment of the present disclosure, a semiconductor device includes: a substrate including an isolation layer and a plurality of active regions that are defined by the isolation layer; a trench disposed in the substrate to cross the isolation layer and the plurality of active regions in a first direction; a semiconductor layer disposed on inner sidewalls of the trench in each of the plurality of active regions; a gate dielectric layer disposed on the inner sidewalls of the trench including the semiconductor layer; and a buried conductive layer disposed in a portion of the trench over the gate dielectric layer.

In accordance with another embodiment of the present disclosure, a method for fabricating a semiconductor device includes: forming an isolation layer over a substrate to define a plurality of active regions; forming a trench in the substrate to cross the isolation layer and the plurality of active regions in a first direction; and forming a semiconductor layer on inner sidewalls and a bottom surface of the trench of the plurality of active regions.

### BRIEF DESCRIPTION OF THE DRAWINGS

FIG. 1A is a plan view illustrating a semiconductor device in accordance with an embodiment of the present disclosure.

FIGS. 1B and 1C are cross-sectional views illustrating the semiconductor device in accordance with the embodiment of the present disclosure.

FIGS. 2A to 6C illustrate a method for fabricating the semiconductor device shown in FIG. 1A to 1C.

FIGS. 7A to 9C illustrate a semiconductor device in accordance with an embodiment of the present disclosure.

FIGS. 10A to 15C illustrate a method for fabricating the semiconductor device shown in FIG. 9A to 9C.

FIGS. 16A to 16C illustrate a semiconductor device in accordance with another example of the embodiment of the present disclosure.

FIGS. 17A to 21C illustrate a method for fabricating the semiconductor device shown in FIGS. 16A to 16C.

FIGS. 22A to 24C illustrate a semiconductor device in accordance with an embodiment of the present disclosure.

### DETAILED DESCRIPTION

Embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only may refer to a case where the first layer is formed directly on the second layer or the substrate but also a case where a third layer exists between the first layer and the second layer or the substrate.

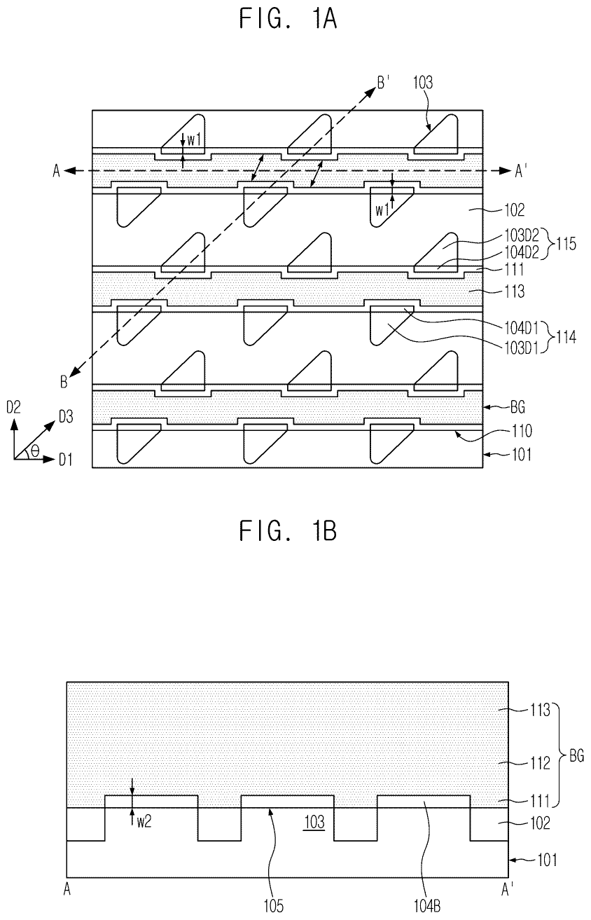

FIG. 1A is a plan view illustrating a semiconductor device in accordance with an embodiment of the present disclosure. FIGS. 1B and 1C are cross-sectional views illustrating the semiconductor device in accordance with the embodiment of the present disclosure. FIG. 1B is a cross-sectional view taken along a line A-A′ shown in FIG. 1A. FIG. 1C is a cross-sectional view taken along a line B-B′ shown in FIG. 1A.

Referring to FIGS. 1A to 1C, the semiconductor device may include a substrate 101, and a buried gate structure BG, a first doped region 114 and a second doped region 115 that are embedded in the substrate 101. The buried gate structure BG and the first and second doped regions 114 and 115 may be a cell transistor. With the buried gate structure, the cell transistor may be able to improve the short channel effect.

The semiconductor device 100 may be a portion of a memory cell. For example, the semiconductor device may be a portion of a memory cell of a Dynamic Random Access Memory (DRAM). The semiconductor device may include a bit line BL and a memory storage element CAP that are electrically connected to the substrate 101.

The bit line BL may be electrically connected to a first doped region 114, and the memory storage element CAP may be electrically connected to a second doped region 115. The bit line BL may be electrically connected to the first doped region 114 through a bit line node 120, and the memory storage element CAP may be electrically connected to the second doped region 115 through a storage node 121. The bit line BL and the memory storage element CAP may be disposed at a higher level than the buried gate structure BG. The bit line BL and the memory storage element CAP may be disposed at different levels. The memory storage element CAP may be disposed at a higher level than the bit line BL. The memory storage element CAP may include a capacitor. According to another embodiment of the present disclosure, the memory storage element CAP may be a thyristor, a phase change material, a magnetic tunnel junction (MTJ), or a variable resistance material.

An isolation layer 102 and active regions 103 may be formed in the substrate 101. The active regions 103 may be defined by the isolation layer 102. The isolation layer 102 may be a shallow trench isolation (STI) region that is formed by a trench etching process. The isolation layer 102 may be formed by filling the shallow trench, for example, an isolation trench, with a dielectric material. The isolation layer 102 may include silicon oxide, silicon nitride, or a combination thereof.

The active regions 103 may be formed of strips and may be arranged in the form of an array. The array of active regions 103 may include a row array and/or a column array. The row array of active regions 103 may include active regions 103 that are arranged in a first direction D1. The column array of active regions 103 may include active regions 103 that are arranged in a second direction D2 which is orthogonal to the first direction D1.

Each active region 103 may have a long axis and a short axis. The long axis direction of each active region 103 may be referred to as a “longitudinal direction of each active region 103”. The short axis direction of each active region 103 may be referred to as a “width direction of each active region 103”. The longitudinal direction of the active regions 103, i.e., a third direction D3, may be non-orthogonal to the first direction D1 and the second direction D2 to form an intersection angle θ. The intersection angle θ between the first direction D1 and the third direction D3 of each active region 103 may range from approximately 10° to 80°, but the concept and spirit of the present disclosure are not limited thereto. The range of the intersection angle θ may be affected by such parameters as the area of each active region 103, the line width of the bit line, and the line width of the buried gate structure BG. Each active region 103 may be a parallelogram, for example, a parallelogram including rounded edges.

The active regions 103 may be arranged in the third direction D3.

A trench 110 may be formed in the substrate 101. Referring to FIG. 1A, the trench 110 may have a line shape extending in the first direction D1. The trench 110 may have a line shape crossing the active regions 103 and the isolation layer 102. One trench 110 may be formed in each active region 103. The trench 110 may cross the center of each of the active regions 103 that are arranged in the first direction D1.

The trenches 110 may be disposed spaced apart from each other in the second direction D2. The trenches 110 may have a shallower depth than the isolation layer 102. In other words, the bottom surface of the trench 110 may be disposed at a higher level than the bottom surface of the isolation layer 102. The trench 110 may be a space where a buried gate structure BG is to be formed, and the trench 110 may be referred to as a ‘gate trench 110’.

The semiconductor layer 104S and 104B may be formed along the profile of the inner sidewalls and bottom surface of the trench 110. The semiconductor layer 104S and 104B may increase the volume of each active region 103. The semiconductor layer 104S and 104B may be selectively formed only in the trench 110 crossing each active region 103. The semiconductor layer 104S and 104B may not be formed over the isolation layer 102. A portion of the semiconductor layer 104S that covers the inner sidewalls of the trench 110 may be a doped region. The semiconductor layer 104B that covers the bottom surface of the trench 110 may serve as a fin 105 or a portion of the fin 105.

The semiconductor layer 104S and 104B may be formed by an epitaxial growth process. The epitaxial growth process may include a selective epitaxial growth (SEG) process. The semiconductor layer 104S and 104B may be selectively formed on the inner sidewalls and bottom surface of the active region 103 that is exposed by the trench 110.

The semiconductor layer 104S formed on the inner sidewalls of the trench 110 may have a first width W1, and the semiconductor layer 104B formed on the bottom surface of the trench 110 may have a second width W2. The first width W1 and the second width W2 may have the same thickness. The semiconductor layer 104S on the inner sidewalls of the trench 110 may be formed to have the same first width W1 on both sides of the trench 110.

Referring to FIG. 1C, the active region 103 between one sidewall of the trench 110 and the isolation layer 102 may have a third width W3. The third width W3 may be wider than the first width W1 and the second width W2, but the concept and spirit of the present disclosure are not limited thereto.

According to another embodiment of the present disclosure, when the third width W3 is too small, the first width W1 of the semiconductor layer 104S may be formed to have a sufficient thickness.

According to an embodiment of the present disclosure, by forming the semiconductor layer 104S on the inner sidewalls of the trench 110, the width of the active region 103 between the trench 110 and the isolation layer 102 may be substantially represented by the sum of the first width W1 and the third width W3. In other words, the width of the active region 103 may expand by the first width W1 of the semiconductor layer 104S that is formed on the inner sidewalls of the trench 110.

In particular, in the case of a Dynamic Random Access Memory (DRAM) of approximately 10 nm Tech or less, the third width W3 may become narrow due to the integration of a semiconductor and thus enters a region where the mobility decreases quantum-mechanically. However, the decrease in the mobility may be prevented by securing the reduced width of the active region through the semiconductor layer 104S and 104B in accordance with the embodiment of the present disclosure.

The height difference between the bottom surface of the trench crossing the isolation layer 102 (shown in FIG. 1B) and the bottom surface of the trench 110 (shown in FIG. 1C) crossing the active region 103 may be the second width W2 of the semiconductor layer 104B on the bottom surface of the trench 110. Therefore, the semiconductor layer 104B on the bottom surface of the trench 110 may function as a fin 105. The fin 105 may be referred to as a saddle fin. The fin 105 may increase the channel width and improve the electrical characteristics.

According to another embodiment of the present disclosure, the bottom surface of the trench 110 crossing the isolation layer 102 may be additionally etched to further increase the height of the fin 105.

The first doped region 114 and the second doped region 115 may be formed in the active region 103. The first doped region 114 may be formed in the active region 103 and the semiconductor layer 104S on one side of the trench 110, and a second doped region 115 may be formed in the active region 103 and the semiconductor layer 104S on the other side of the trench 110. The first doped region 114 may include a first active doped region 103D1 and a first extended doped region 104D1. The second doped region 115 may include a second active doped region 103D2 and a second extended doped region 104D2. The first and second active doped regions 103D1 and 103D2 may refer to an active region 103 that is doped with an impurity. The first and second extended doped regions 104D1 and 104D2 may refer to the semiconductor layer 104S that is doped with an impurity.

According to the embodiment of the present disclosure, the areas of the first and second doped regions 114 and 115 may be increased as much as the widths of the first and second extended doped regions 104D1 and 104D2 by additionally forming the semiconductor layer 104S on both sidewalls of the trench 110. Accordingly, there is an effect of increasing the overlay margin between the substrate 101 and the upper structure (e.g., a bit line BL or a memory storage element CAP).

The first and second doped regions 114 and 115 may not be disposed on a straight line in the second direction D2. The first and second doped regions 114 and 115 may be disposed to be misaligned on the left and right in the second direction D2 so that there may be no overlapping region.

The first doped region 114 and the second doped region 115 may be regions doped with conductive dopants. For example, the conductive dopant may include phosphorus (P), arsenic (As), antimony (Sb), or boron (B). The first doped region 114 and the second doped region 115 may be doped with dopants of the same conductivity type. The first doped region 114 and the second doped region 115 may be disposed in the active region 103 and the semiconductor layer 104S on both sides of the trench 110. In other words, the first and second doped regions 114 and 115 may be disposed to be spaced apart from each other by the trench 110. The bottom surfaces of the first doped region 114 and the second doped region 115 may be disposed at a predetermined depth from the top surface of the substrate 101. The bottom surfaces of the first doped region 114 and the second doped region 115 may be higher than the bottom surface of the trench 110. The first doped region 114 may be referred to as a ‘source region 114’, and the second doped region 115 may be referred to as a ‘drain region 115’. The buried gate structure BG may define a channel between the first doped region 114 and the second doped region 115. The channel may be defined along the profile of the trench 110.

The buried gate structure BG may be embedded in the trench 110. The buried gate structure BG may be disposed in the active region 103 between the first doped region 114 and the second doped region 115 to extend into the isolation layer 102. The bottom surface of the portion of the buried gate structure BG disposed in the active region 103 and the bottom surface of the portion of the buried gate structure BG disposed in the isolation layer 102 may be disposed at different levels. When the fin 105 is omitted, the bottom surface of the portion of the buried gate structure BG disposed in the active region 103 and the bottom surface of the portion of the buried gate structure BG disposed in the isolation layer 102 may be disposed at the same level.

The buried gate structure BG may include a gate dielectric layer 111 that covers the semiconductor layer 104S and 104B formed on the bottom surface and inner sidewalls of the trench 110, a buried conductive layer 112 that fills the lower portion of the trench 110 over the gate dielectric layer 111, and a gate capping layer 113 that fills the upper portion of the trench 110 over the buried conductive layer 112.

The gate dielectric layer 111 may be formed over the semiconductor layer 104S and 104B. The gate dielectric layer 111 may be conformally formed along the surface of the semiconductor layer 104S and 104B. The gate dielectric layer 111 may include silicon oxide, silicon nitride, silicon oxynitride, a high-k material, or a combination thereof. The high-k material may include a material having a dielectric constant which is greater than the dielectric constant of silicon oxide. For example, the high-k material may include a material having a dielectric constant which is greater than approximately 3.9. For another example, the high-k material may include a material having a dielectric constant which is greater than approximately 10. For yet another example, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material.

The buried conductive layer 112 may fill a portion of the trench 110. The buried conductive layer 112 in the trench 110 may be formed in a wavy line shape extending in the first direction D1 by the semiconductor layer 104S. The buried conductive layer 112 may be referred to as a “gate electrode 112”. The buried conductive layer 112 may be a low-resistance material to lower a gate sheet resistance. The buried conductive layer 112 may include a semiconductor material, a metal-based material, or a combination thereof. The buried conductive layer 112 may include polysilicon, a metal, a metal nitride, or a combination thereof. For example, the buried conductive layer 112 may include N-type doped polysilicon, tantalum nitride (TaN), titanium nitride (TiN), tungsten (W), tungsten nitride (WN), molybdenum (Mo), ruthenium (Ru), or a combination thereof. According to another embodiment of the present disclosure, the buried conductive layer 112 may be formed of titanium nitride alone or molybdenum alone. According to yet another embodiment of the present disclosure, the buried conductive layer 112 may be formed of a stack of titanium nitride and tungsten (i.e., TiN/W) or a stack of titanium nitride and polysilicon (i.e., TiN/Polysilicon).

According to another embodiment of the present disclosure, the buried conductive layer 112 may apply a dual gate structure including upper and lower gates. According to yet another embodiment of the present disclosure, the buried conductive layer 112 may apply a triple gate structure including upper, middle, and lower gates.

According to another embodiment of the present disclosure, the buried conductive layer 112 may have a high work function. In this instance, the high work function may refer to a work function which is higher than the mid-gap work function of silicon. The low work function may refer to a work function which is lower than the mid-gap work function of silicon. To be specific, the high work function may have a work function which is higher than approximately 4.5 eV, and the low work function may have a work function which is lower than approximately 4.5 eV. The buried conductive layer 112 may include P-type polysilicon or nitrogen-rich titanium nitride.

According to another embodiment of the present disclosure, the buried conductive layer 112 may have an increased high work function. The buried conductive layer 112 may include a metal silicon nitride. The metal silicon nitride may be a metal nitride doped with silicon. The buried conductive layer 112 may include a metal silicon nitride with a controlled silicon content. For example, the buried conductive layer 112 may include tantalum silicon nitride (TaSiN) or titanium silicon nitride (TiSiN). Titanium nitride may have a high work function, and silicon may be added to the titanium nitride to further increase the work function of the titanium nitride. Titanium silicon nitride may have a controlled silicon content to have an increased high work function. According to another embodiment of the present disclosure, the buried conductive layer 112 may include titanium aluminum nitride (TiAlN).

A gate capping layer 113 may be formed over the buried conductive layer 112. The gate capping layer 113 may prevent oxidation of the buried conductive layer 112. The gate capping layer 113 may be formed in the trench 110 to electrically insulate the upper structure, such as a contact, a conductive line and the like, from the buried conductive layer 112. According to one embodiment of the present disclosure, the top surface of the gate capping layer 113 may be disposed at the same level as the top surface of the substrate 101.

The gate capping layer 113 may include a dielectric material. The gate capping layer 113 may include silicon nitride or silicon oxide, but the concept and spirit of the present disclosure are not limited thereto. According to another embodiment of the present disclosure, the gate capping layer 113 may include a low-k material. The gate capping layer 113 may be formed as a single layer. According to another embodiment of t he present disclosure, the gate capping layer 113 may be formed to have a multi-layer structure of different materials.

As described above, the embodiment of the present disclosure may increase the widths of the first and second doped regions 114 and 115 by forming the semiconductor layer 104S on the inner sidewalls of the trench 110 crossing the active region 103. Also, since the semiconductor layer 104S formed on one sidewall of the trench 110 and the semiconductor layer 104S formed on the other sidewall of the trench 110 are not disposed on a straight line in the second direction D2, the reduction in the line width of the trench 110 due to the semiconductor layer 104S may be minimized. As a result, since the reduction in the volume of the buried conductive layer 112 buried in the trench 110 may be minimized, the increase in the resistance of the semiconductor device may be minimized.

Referring to FIGS. 1B and 1C, the semiconductor device may include a plurality of memory cells, and the neighboring memory cells may be separated from each other by the isolation layer 102. One memory cell may be formed over one active region 103, and this may be referred to as a memory cell of a ‘1G1A (one Gate-one Active) structure.’ In t he memory cell of the 1G1A structure, a bit line BL may be coupled to one active region 103, so one memory cell may be coupled to one bit line BL. The memory cell of the 1G1A structure may include 1T1C (one Transistor-one Capacitor). As a comparative example, in a general DRAM, two memory cells may be formed in one active region, and two gate electrodes may be formed in one active region, and two neighboring memory cells may share one bit line.

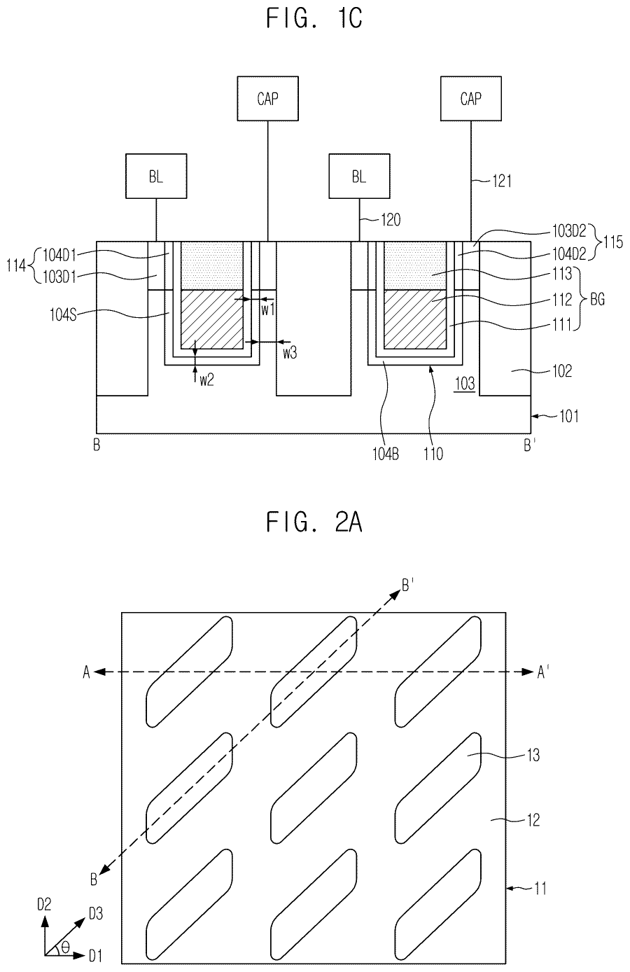

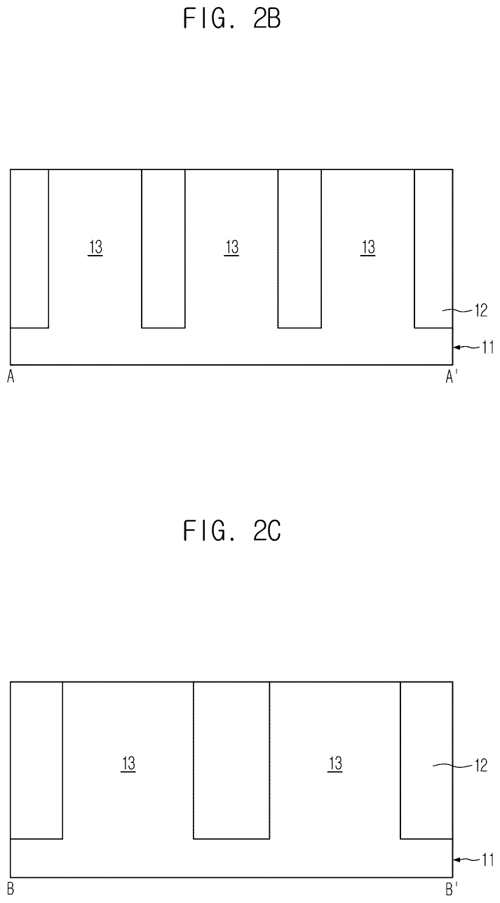

FIGS. 2A to 6C illustrate a method for fabricating the semiconductor device shown in FIG. 1A to 1C. FIGS. 2A, 3A, 4A, 5A and 6A are plan views illustrating a method for fabricating the semiconductor device in accordance with the embodiment of the present disclosure. FIGS. A to C of each figure number may indicate the same process step. FIGS. 2B, 3B, 4B, 5B and 6B are process cross-sectional views taken along a line A-A′ shown in FIGS. 2A, 3A, 4A, 5A and 6A, respectively. FIGS. 2C, 3C, 4C, 5C and 6C are process cross-sectional views taken along a line B-B′ shown in FIGS. 2A, 3A, 4A, 5A and 6A, respectively. To help understanding, FIGS. A to C of each figure number may be described together.

Referring to FIGS. 2A to 2C, an isolation layer 12 may be formed over a substrate 11 to define active regions 13.

The substrate 11 may be a material suitable for semiconductor processing. The substrate 11 may include a semiconductor substrate. The substrate 11 may be formed of a material containing silicon. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may also include another semiconductor material, such as germanium. The substrate 11 may also include a III/V-group semiconductor substrate, for example, a compound semiconductor substrate, such as gallium arsenide (GaAs). The substrate 11 may also include an SOI (Silicon-On-Insulator) substrate.

The isolation layer 12 may be a Shallow Trench Isolation region (STI) that is formed by a trench etching process. The isolation layer 12 may be formed by filling an isolation trench with a dielectric material. The isolation layer 12 may include silicon oxide, silicon nitride, or a combination thereof.

The active regions 13 may be formed of strips and may be arranged in the form of an array. The array of the active regions 13 may include a row array and/or a column array. The row array of the active regions 13 may include active regions 13 that are arranged in the first direction D1. The column array of the active regions 13 may include active regions 13 that are arranged in the second direction D2 which is orthogonal to the first direction D1. The longitudinal direction of the active regions 13, i.e., the third direction D3, may be non-orthogonal to the first direction D1 and the second direction D2 to form an intersection angle θ. The intersection angle θ between the first direction D1 and the third direction D3 of each active region 13 may range from approximately 10° to 80°, but the concept and spirit of the embodiment of the present disclosure are not limited thereto. The range of the intersection angle θ may be affected by such parameters as the area of each active region 13, the line width of the bit line, and the line width of the buried gate structure.

The active regions 13 may be arranged in the third direction D3.

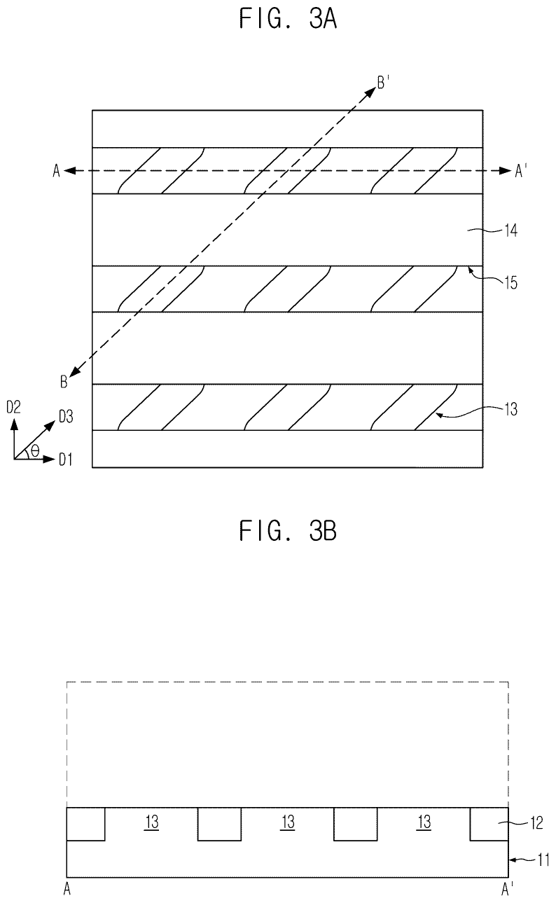

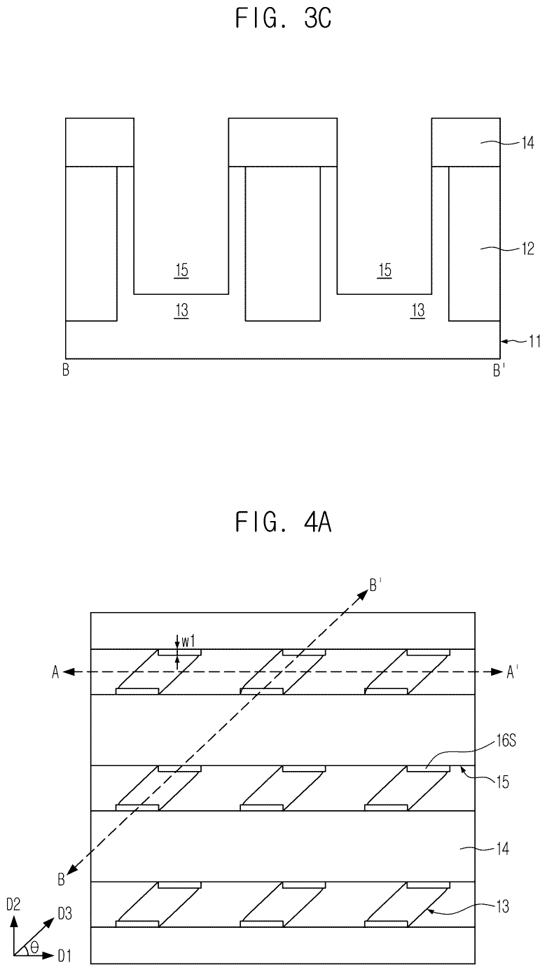

Referring to FIGS. 3A to 3C, a first hard mask layer 14 may be formed over the active regions 13 and the isolation layer 12.

The first hard mask layer 14 may have a line shape extending in the first direction D1 and disposed to be spaced apart in the second direction D2. The first hard mask layer 14 may include a dielectric material having an etching selectivity with respect to the active regions 13 and the isolation layer 12. The first hard mask layer 14 may be formed in a single-layer structure or a stacked structure. The stacked structure of the first hard mask layer 14 may include dielectric materials of different etching selectivities.

Subsequently, a trench 15 extending in the first direction D1 may be formed by etching the active regions 13 and the isolation layer 12 with the first hard mask layer 14 used as an etching barrier.

One trench 15 may be formed in each active region 13. The trench 15 may cross the center of each active region 13. The trenches 15 may be disposed to be spaced apart from each other in the second direction D2. The depth of the trench 15 may be shallower than the depth of the isolation layer 12. In other words, the bottom surface of the trench 15 may be disposed at a higher level than the bottom surface of the isolation layer 12. According to another embodiment of the present disclosure, the bottom portion of the trench 15 may have a curvature. The trench 15 may be a space where a buried gate structure is to be formed, and the trench 15 may be referred to as a “gate trench 15”.

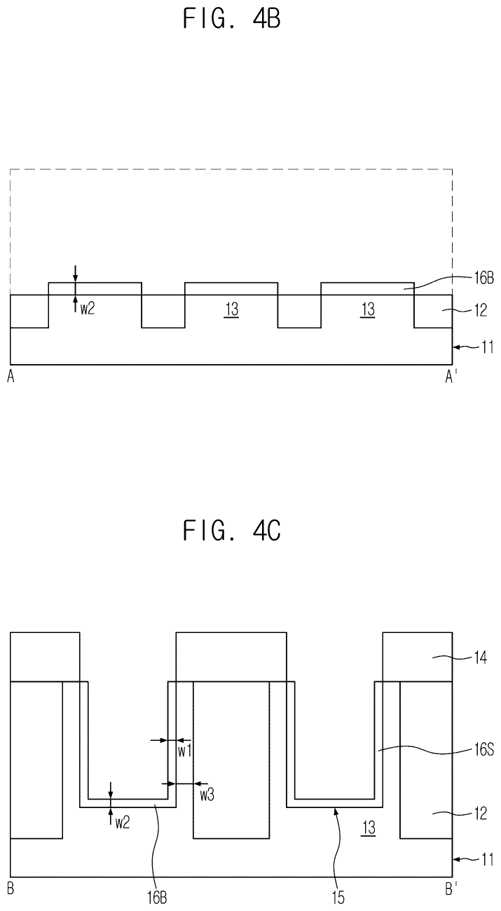

Referring to FIGS. 4A to 4C, a semiconductor layer 16S and 16B that covers the inner sidewalls and bottom surface of the trench 15 may be formed.

The semiconductor layer 16S and 16B may increase the volume of each active region 13. The semiconductor layer 16S and 16B may be selectively formed only in the trench 15 crossing each active region 13. The semiconductor layer 16S and 16B may not be formed over the isolation layer 12. A portion of the semiconductor layer 16S that covers the inner sidewalls of the trench 15 may be a doped region. The semiconductor layer 16B that covers the bottom surface of the trench 15 may serve as a fin or a portion of the fin.

The semiconductor layer 16S and 16B may be formed by an epitaxial growth process. The epitaxial growth process may be a Selective Epitaxial Growth (SEG) process, and the semiconductor layer 16S and 16B may be selectively formed on the inner sidewalls and bottom surface of the active region 13 that is exposed by the trench 15.

The semiconductor layer 16S formed on the inner sidewalls of the trench 15 may have a first width W1, and the semiconductor layer 16B formed on the bottom surface of the trench 15 may have a second width W2. The first width W1 and the second width W2 may have the same thickness. The semiconductor layer 16S formed on the inner sidewalls of the trench 15 may be formed to have the same first width W1 on both sides of the trench 15.

Referring to FIG. 4C, the active region 13 between one sidewall of the trench 15 and the isolation layer 12 may have a third width W3. The third width W3 may be wider than the first width W1 and the second width W2, but the concept and spirit of the present disclosure are not limited thereto. According to the embodiment of the present disclosure, by forming the semiconductor layer 16S on the inner sidewalls of the trench 15, the width of the active region 13 may be substantially represented by the sum of the first width W1 and the third width W3. In other words, the width of the active region 13 may expand as much as the first width W1 of the semiconductor layer 16S that is formed on the inner sidewalls of the trench 15.

Referring to FIG. 4B, the height difference between the bottom surface of the trench 15 crossing the isolation layer 12 and the bottom surface of the trench 15 crossing the active region 13 may be the second width W2 of the semiconductor layer 16B on the bottom surface of the trench 15. Therefore, the semiconductor layer 16B on the bottom surface of the trench 15 may function as a fin. The fin may be referred to as a saddle fin. The fin may increase the channel width and improve the electrical characteristics.

According to another embodiment of the present disclosure, the semiconductor layer 16B on the bottom surface of the trench 15 may be omitted. According to yet another embodiment of the present disclosure, the bottom surface of the trench 15 crossing the isolation layer 12 may be additionally etched to further increase the height of the fin.

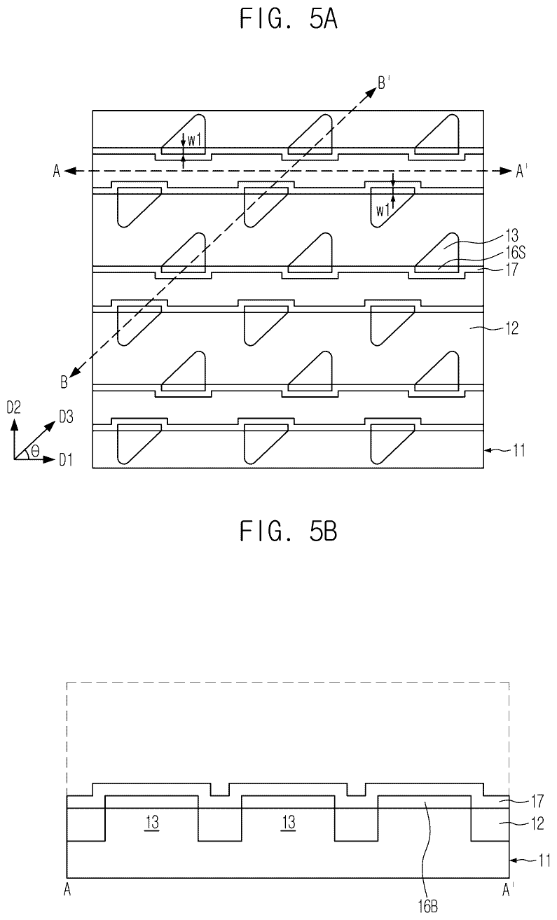

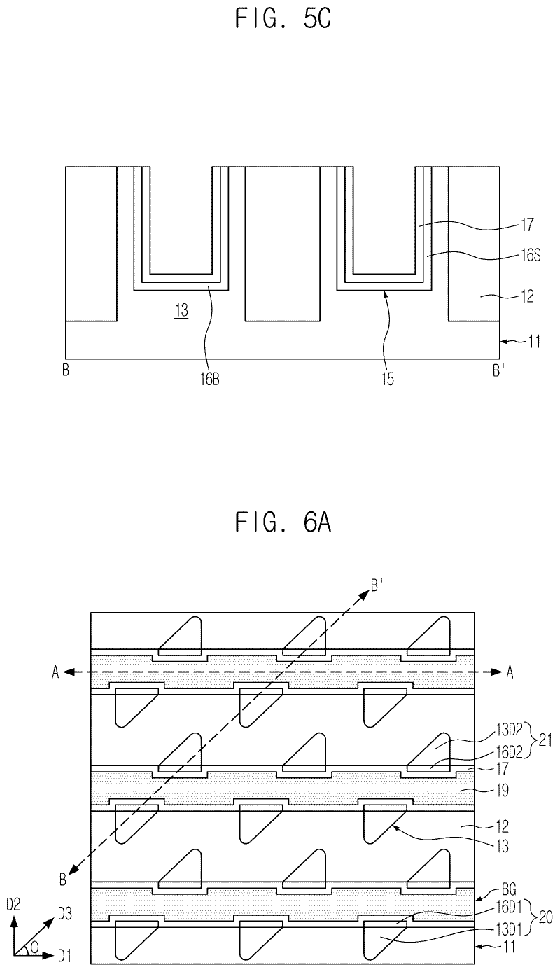

Referring to FIGS. 5A to 5C, a gate dielectric layer 17 that covers the inner surface of the trench 15 may be formed.

The gate dielectric layer 17 may be conformally formed on the bottom surface and inner sidewalls of the trench 15. Also, since the semiconductor layer 16S and 16B is formed on the bottom surface and inner sidewalls of the trench 15 crossing the active region 13, the gate dielectric layer 17 may uniformly cover the bottom surface and inner sidewalls of the trench 15 and the semiconductor layer 16S and 16B. The gate dielectric layer 17 may include silicon oxide, silicon nitride, silicon oxynitride, a high-k material, or a combination thereof. The high-k material may include a material having a dielectric constant which is greater than the dielectric constant of silicon oxide. For example, the high-k material may include a material having a dielectric constant which is greater than approximately 3.9. For another example, the high-k material may include a material having a dielectric constant which is greater than approximately 10. For yet another example, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material. The gate dielectric layer 17 may include a metal oxide.

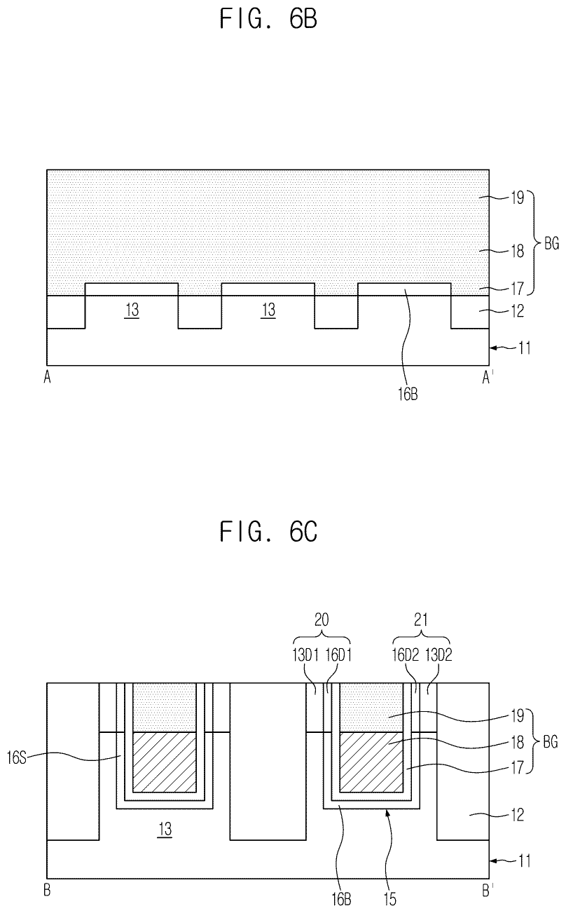

Referring to FIGS. 6A to 6C, a buried gate structure BG may be formed by sequentially stacking a buried conductive layer 18 and a gate capping layer 19 over the gate dielectric layer 17.

The buried conductive layer 18 may be referred to as a “gate electrode 18”. The buried conductive layer 18 may be a low-resistance material to lower the gate sheet resistance. The buried conductive layer 18 may include a semiconductor material, a metal-based material, or a combination thereof. The buried conductive layer 18 may include polysilicon, a metal, a metal nitride, or a combination thereof. For example, the buried conductive layer 18 may include N-type doped polysilicon, tantalum nitride (TaN), titanium nitride (TiN), tungsten (W), tungsten nitride (WN), molybdenum (Mo), ruthenium (Ru), or a combination thereof. According to another embodiment of the present disclosure, the buried conductive layer 18 may be formed of titanium nitride alone or molybdenum alone. According to yet another embodiment of the present disclosure, the buried conductive layer 18 may be formed of a stack of titanium nitride and tungsten (i.e., TiN/W) or a stack of titanium nitride and polysilicon (i.e., TiN/Polysilicon).

According to another embodiment of the present disclosure, the buried conductive layer 18 may apply a dual gate structure including upper and lower gates. According to yet another embodiment of the present disclosure, the buried conductive layer 18 may apply a triple gate structure including upper, middle, and lower gates.

According to another embodiment of the present disclosure, the buried conductive layer 18 may have a high work function. The buried conductive layer 18 may include P-type polysilicon or nitrogen-rich titanium nitride.

According to another embodiment of the present disclosure, the buried conductive layer 18 may have an increased high work function. The buried conductive layer 18 may include a metal silicon nitride. The metal silicon nitride may be a metal nitride that is doped with silicon. The buried conductive layer 18 may include a metal silicon nitride having a controlled silicon content. For example, the buried conductive layer 18 may include tantalum silicon nitride (TaSiN) or titanium silicon nitride (TiSiN). Titanium nitride may have a high work function, and silicon may be added to the titanium nitride to further increase the work function of the titanium nitride. The silicon content of the titanium silicon nitride may be adjusted to have an increased high work function. According to another embodiment of the present disclosure, the buried conductive layer 18 may include titanium aluminum nitride (TiAlN).

The gate capping layer 19 may serve to protect the buried conductive layer 18. The gate capping layer 19 may fill the upper portion of the trench 15 over the buried conductive layer 18. The top surface of the gate capping layer 19 may be disposed at the same level as the top surfaces of the first and second source/drain regions 20 and 21 (alternately referred to as first and second doped regions 20 and 21, as described below). The gate capping layer 19 may include a dielectric material. The gate capping layer 19 may include silicon nitride, silicon oxynitride, or a combination thereof. According to another embodiment of the present disclosure, the gate capping layer 19 may include a combination of silicon nitride and silicon oxide. The gate capping layer 19 may include a silicon nitride liner and a spin-on dielectric (SOD).

Subsequently, first and second doped regions 20 and 21 may be formed in the substrate 11 on both sides of the trench 15. A first doped region 20 may be formed in the active region 13 and the semiconductor layer 16S on one side of the trench 15, and a second doped region 21 may be formed in the active region 13 and the semiconductor layer 16S on the other side of the trench 15. The first doped region 20 may include a first active doped region 13D1 and a first extended doped region 16D1. The second doped region 21 may include a second active doped region 13D2 and a second extended doped region 16D2. The first and second active doped regions 13D1 and 13D2 may refer to an active region 13 that is doped with an impurity. The first and second extended doped regions 16D1 and 16D2 may refer to the semiconductor layer 16S that is doped with an impurity.

According to this embodiment of the present disclosure, by additionally forming the semiconductor layer 16S on both sidewalls of the trench 15, the areas of the first and second doped regions 20 and 21 may be increased as much as the widths of the first and second extended doped regions 16D1 and 16D2. Accordingly, there is an effect of increasing the overlay margin between the substrate 11 and the upper structure (e.g., a bit line or a memory element).

The first and second doped regions 20 and 21 may not be disposed on a straight line in the second direction D2. The first and second doped regions 20 and 21 may be disposed to be misaligned on the left and right in the second direction D2 so that there may be no overlapping region.

The first doped region 20 and the second doped region 21 may be regions that are doped with a conductive dopant, respectively. For example, the conductive dopant may include phosphorus (P), arsenic (As), antimony (Sb), or boron (B). The first and second doped regions 20 and 21 may be doped with dopants of the same conductivity type. The first and second doped regions 20 and 21 may be arranged to be spaced apart from each other by the trench 15. The bottom surfaces of the first and second doped regions 20 and 21 may be disposed at a predetermined depth from the top surface of the substrate 11. The bottom surfaces of the first and second doped regions 20 and 21 may be higher than the bottom surface of the trench 15. The first doped region 20 may be referred to as a “source region 20” or a “first impurity region 20”, and the second doped region 21 may be referred to as a “drain region 21” or a “second impurity region 21”.

A buried gate structure BG may be formed by sequentially gap-filling the trench 15 with the gate dielectric layer 17, the buried conductive layer 18 and the gate capping layer 19. The buried gate structure BG may define a channel between the first doped region 20 and the second doped region 21. The channel may be defined along the profile of the trench 15.

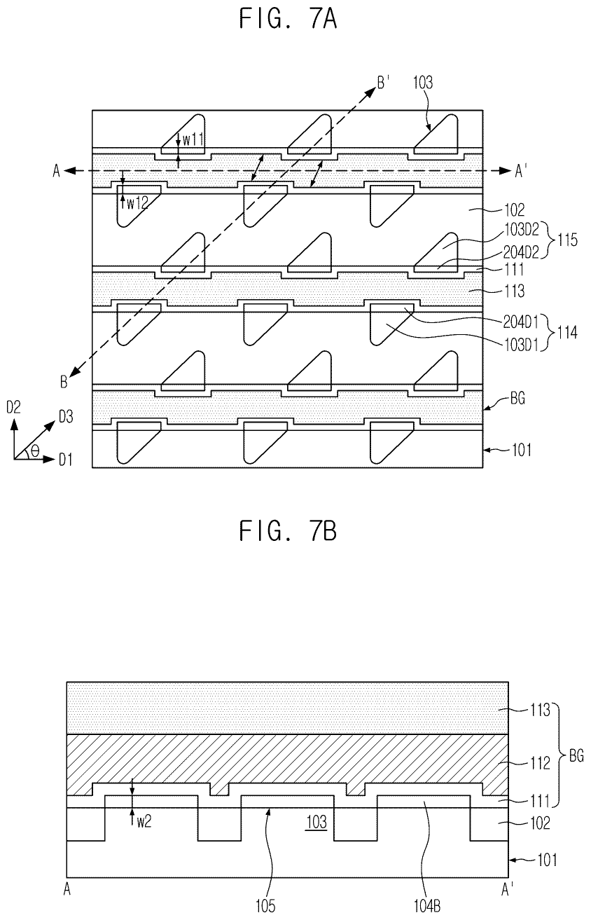

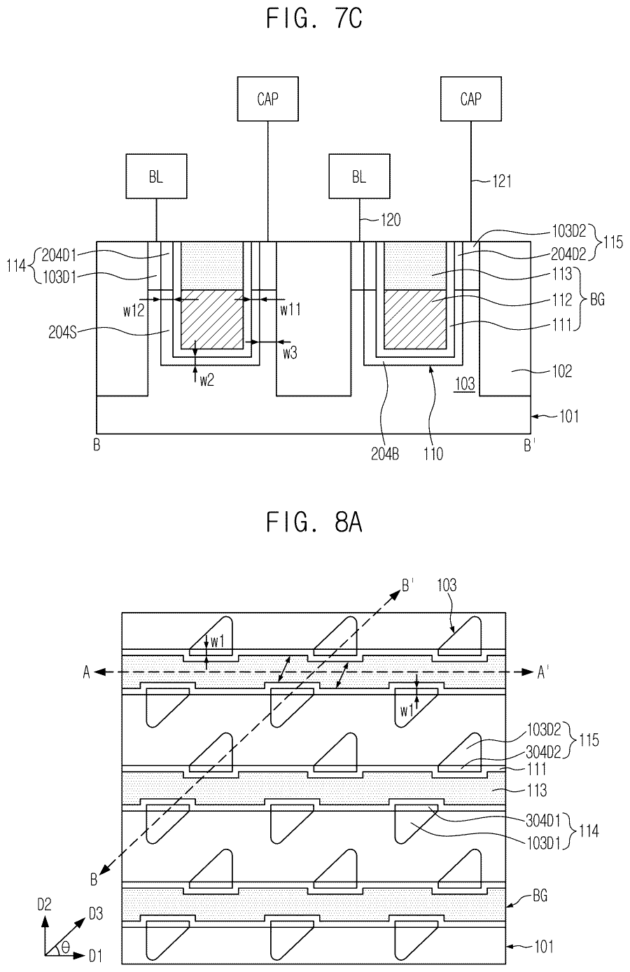

FIGS. 7A to 9C illustrate a semiconductor device in accordance with example embodiments of the present disclosure. FIGS. 7B, 8B and 9B are process cross-sectional views taken along a line A-A′ shown in FIGS. 7A, 8A and 9A. FIGS. 7C, 8C and 9C are process cross-sectional views taken along a line B-B′ shown in FIGS. 7A, 8A and 9A. FIGS. 7A to 9C may include the same structure as that of FIG. 1A to 1C except for the buried gate structure BG and the first and second doped regions 114 and 115. For the sake of convenience in description, description on the same structure may be minimized or omitted.

Referring to FIGS. 7A to 7C, the semiconductor device may include a substrate 101, and a buried gate structure BG, a first doped region 114, and a second doped region 115 that are embedded in the substrate 101. The buried gate structure BG and the first and second doped regions 114 and 115 may be a cell transistor. With the buried gate structure, the cell transistor may be able to improve the short channel effect.

The semiconductor device 100 may be a portion of a memory cell. For example, the semiconductor device may be a portion of a memory cell of a DRAM. The semiconductor device may include a bit line BL and a memory storage element CAP that are electrically connected to the substrate 101.

An isolation layer 102 and active regions 103 may be formed in the substrate 101. The active regions 103 may be defined by the isolation layer 102.

The active regions 103 may be formed of strips and may be arranged in the form of an array. The array of active regions 103 may include a row array and/or a column array. The row array of active regions 103 may include active regions 103 that are arranged in the first direction D1. The column array of active regions 103 may include active regions 103 that are arranged in the second direction D2 which is orthogonal to the first direction D1.

Each active region 103 may have a long axis and a short axis. The long axis direction of each active region 103 may be referred to as a “longitudinal direction of each active region 103”. The short axis direction of each active region 103 may be referred to as a “width direction of each active region 103”. The longitudinal direction of the active regions 103, i.e., the third direction D3, may be non-orthogonal to the first direction D1 and the second direction D2 to form an intersection angle θ. The intersection angle θ between the first direction D1 and the third direction D3 of each active region 103 may range from approximately 10° to 80°, but the concept and spirit of the embodiment of the present disclosure are not limited thereto. The range of the intersection angle θ may be affected by such parameters as the area of each active region 103, the line width of the bit line, and the line width of the buried gate structure BG. Each active region 103 may be a parallelogram, for example, a parallelogram including rounded edges.

The active regions 103 may be arranged in the third direction D3.

A trench 110 may be formed in the substrate 101.

A semiconductor layer 204S and 204B may be formed along the profile of the inner sidewalls and bottom surface of the trench 110. The semiconductor layer 204S and 204B may serve to increase the volume of each active region 103. The semiconductor layer 204S and 204B may be selectively formed only in the trench 110 crossing each active region 103. The semiconductor layer 204S and 204B may not be formed over the isolation layer 102. A portion of the semiconductor layer 204S that covers the inner sidewalls of the trench 110 may be a doped region. The semiconductor layer 204B that covers the bottom surface of the trench 110 may serve as the fin 105 or a portion of the fin 105.

The semiconductor layer 204S and 204B may be formed by an epitaxial growth process. The epitaxial growth process may include a Selective Epitaxial Growth (SEG) process. The semiconductor layer 204S and 204B may be selectively formed on the inner sidewalls and bottom surface of the active region 103 that is exposed by the trench 110.

The semiconductor layer 204S formed on the inner sidewalls of the trench 110 may have a first width w11, and the semiconductor layer 204B formed on the bottom surface of the trench 110 may have a second width w12.

The semiconductor layer 204S formed on the inner sidewalls of the trench 110 may have different thicknesses on both sidewalls of the trench 110. In other words, the thickness of the first side width w11 of the semiconductor layer 204S formed on one sidewall of the trench 110 and the thickness of the second side width w12 of the semiconductor layer 204S formed on the other sidewall of the trench 110 may be different from each other. The first side width w11 may be smaller than the second side width w12.

Therefore, the width of the first doped region 114 may be larger than the width of the second doped region 115.

According to another embodiment of the present disclosure, the first side width w11 may be larger than the second side width w12. The width of the first doped region 114 may be smaller than the width of the second doped region 115.

Referring to FIG. 7B, the height difference between the bottom surface of the trench 110 crossing the isolation layer 102 and the bottom surface of the trench 110 crossing the active region 103 may be the second width w2 of the semiconductor layer 204B on the bottom surface of the trench 110. Therefore, the semiconductor layer 204B on the bottom surface of the trench 110 may function as the fin 105. The fin 105 may be referred to as a saddle fin. The fin 105 may increase the channel width and improve the electrical characteristics.

According to another embodiment of the present disclosure, the bottom surface of the trench 110 crossing the isolation layer 102 may be additionally etched to further increase the height of the fin 105.

The first doped region 114 and the second doped region 115 may be formed in the active region 103. A first doped region 114 may be formed in the active region 103 and the semiconductor layer 204S on one side of the trench 110, and a second doped region 115 may be formed in the active region 103 and the semiconductor layer 204S on the other side of the trench 110. The first doped region 114 may include a first active doped region 103D1 and a first extended doped region 204D1. The second doped region 115 may include a second active doped region 103D2 and a second extended doped region 204D2. The first and second active doped regions 103D1 and 103D2 may refer to the active region 103 that is doped with an impurity. The first and second extended doped regions 204D1 and 204D2 may refer to the semiconductor layer 204S that is doped with an impurity.

According to the embodiment of the present disclosure, by additionally forming the semiconductor layer 204S on both sidewalls of the trench 110, the areas of the first and second doped regions 114 and 115 may be increased as much as the widths of the first and second extended doped regions 204D1 and 204D2. Accordingly, there is an effect of increasing the overlay margin between the substrate 101 and the upper structure (e.g., a bit line BL or a memory element CAP).

The first and second doped regions 114 and 115 may not be disposed on a straight line in the second direction D2. The first and second doped regions 114 and 115 may be disposed to be misaligned on the left and right in the second direction D2 so that there may be no overlapping region.

The first doped region 114 and the second doped region 115 may be regions doped with conductive dopants. For example, the conductive dopant may include phosphorus (P), arsenic (As), antimony (Sb), or boron (B). The first doped region 114 and the second doped region 115 may be doped with dopants of the same conductivity type. The first doped region 114 and the second doped region 115 may be disposed in the active region 103 and the semiconductor layer 104S on both sides of the trench 110. In other words, the first and second doped regions 114 and 115 may be disposed to be spaced apart from each other by the trench 110. The bottom surfaces of the first doped region 114 and the second doped region 115 may be disposed at a predetermined depth from the top surface of the substrate 101. The bottom surfaces of the first doped region 114 and the second doped region 115 may be higher than the bottom surface of the trench 110. The first doped region 114 may be referred to as a “source region 114”, and the second doped region 115 may be referred to as a “drain region 115”. The buried gate structure BG may define a channel between the first doped region 114 and the second doped region 115. The channel may be defined along the profile of the trench 110.

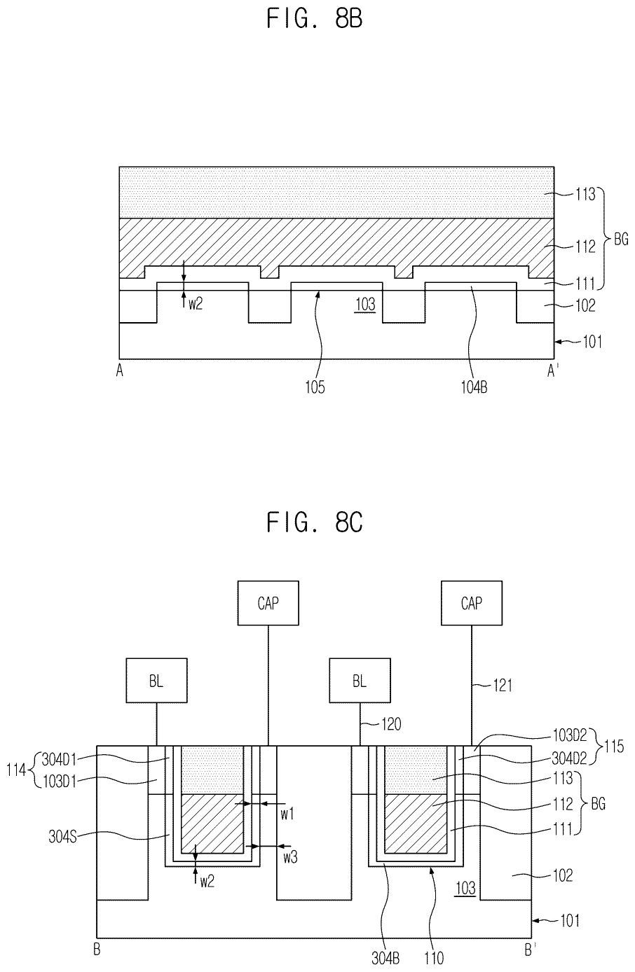

Referring to FIGS. 8A to 8C, the semiconductor device may include a substrate 101. The semiconductor device may also include a buried gate structure BG, a first doped region 114, and a second doped region 115 that are embedded in the substrate 101. The buried gate structure BG and the first and second doped regions 114 and 115 may be (form) a cell transistor. With the buried gate structure, the cell transistor may be able to improve the short channel effect.

The active regions 103 may be formed of strips and may be arranged in the form of an array. The array of active regions 103 may include a row array and/or a column array. The row array of active regions 103 may include active regions 103 that are arranged in the first direction D1. The column array of active regions 103 may include active regions 103 that are arranged in the second direction D2 which is orthogonal to the first direction D1.

Each active region 103 may have a long axis and a short axis. The long axis direction of each active region 103 may be referred to as a “longitudinal direction of each active region 103”. The short axis direction of each active region 103 may be referred to as a “width direction of each active region 103”. The longitudinal direction of the active regions 103, i.e., the third direction D3, may be non-orthogonal to the first direction D1 and the second direction D2 to form an intersection angle θ. The intersection angle θ between the first direction D1 and the third direction D3 of each active region 103 may range from approximately 10° to 80°, but the concept and spirit of the embodiment of the present disclosure are not limited thereto. The range of the intersection angle θ may be affected by such parameters as the area of each active region 103, the line width of the bit line, and the line width of the buried gate structure BG. Each active region 103 may be a parallelogram, for example, a parallelogram including rounded edges.

The active regions 103 may be arranged in the third direction D3.

A trench 110 may be formed in the substrate 101.

A semiconductor layer 304S and 304B may be formed along the profile of the inner sidewalls and bottom surface of the trench 110. The semiconductor layer 304S and 304B may serve to increase the volume of each active region 103. The semiconductor layer 304S and 304B may be selectively formed only in the trench 110 crossing each active region 103. The semiconductor layer 304S and 304B may not be formed over the isolation layer 102. A portion of the semiconductor layer 304S that covers the inner sidewalls of the trench 110 may be a doped region. The semiconductor layer 304B that covers the bottom surface of the trench 110 may serve as a fin 105 or a portion of the fin 105.

The semiconductor layer 304S and 304B may be formed by an epitaxial growth process. The epitaxial growth process may include a selective epitaxial growth (SEG) process. The semiconductor layer 304S and 304B may be selectively formed on the inner sidewalls and bottom surface of the active region 103 that is exposed by the trench 110.

The semiconductor layer 304S formed on the inner sidewalls of the trench 110 may have a first width W1, and the semiconductor layer 304B formed on the bottom surface of the trench 110 may have a second width W2.

The thickness of the semiconductor layer 304S formed on the inner sidewalls of the trench 110 and the thickness of the semiconductor layer 304B formed on the bottom surface of the trench 110 may be different from each other. In other words, the first width W1 of the semiconductor layer 304S formed on the inner sidewalls of the trench 110 may be larger than the second width W2 of the semiconductor layer 304B formed on the bottom surface of the trench 110.

Referring to FIG. 8B, the height difference between the bottom surface of the trench 110 crossing the isolation layer 102 and the bottom surface of the trench 110 crossing the active region 103 may be the second width W2 of the semiconductor layer 304B on the bottom surface of the trench 110. Accordingly, the semiconductor layer 304B on the bottom surface of the trench 110 may function as the fin 105. The fin 105 may be referred to as a saddle fin. The fin 105 may increase the channel width and improve the electrical characteristics.

The first doped region 114 and the second doped region 115 may be formed in the active region 103. The first doped region 114 may be formed in the active region 103 and the semiconductor layer 304S on one side of the trench 110, and the second doped region 115 may be formed in the active region 103 and the semiconductor layer 304S on the other side of the trench 110. The first doped region 114 may include a first active doped region 103D1 and a first extended doped region 304D1. The second doped region 115 may include a second active doped region 103D2 and a second extended doped region 304D2. The first and second active doped regions 103D1 and 103D2 may refer to an active region 103 that is doped with an impurity. The first and second extended doped regions 304D1 and 304D2 may refer to the semiconductor layer 304S that is doped with an impurity.

According to the embodiment of the present disclosure, by additionally the forming semiconductor layer 304S on both sidewalls of the trench 110, the areas of the first and second doped regions 114 and 115 may be increased as much as the widths of the first and second extended doped regions 304D1 and 304D2. Accordingly, there is an effect of increasing the overlay margin between the substrate 101 and the upper structure (e.g., a bit line BL or a memory element CAP).

The first and second doped regions 114 and 115 may not be disposed on a straight line in the second direction D2. The first and second doped regions 114 and 115 may be disposed to be misaligned on the left and right in the second direction D2 so that there may be no overlapping region.

The first doped region 114 and the second doped region 115 may be regions doped with conductive dopants. For example, the conductive dopant may include phosphorus (P), arsenic (As), antimony (Sb), or boron (B). The first doped region 114 and the second doped region 115 may be doped with dopants of the same conductivity type. The first doped region 114 and the second doped region 115 may be disposed in the active region 103 and the semiconductor layer 304S on both sides of the trench 110. In other words, the first and second doped regions 114 and 115 may be arranged to be spaced apart from each other by the trench 110. The bottom surfaces of the first doped region 114 and the second doped region 115 may be disposed at a predetermined depth from the top surface of the substrate 101. The bottom surfaces of the first doped region 114 and the second doped region 115 may be higher than the bottom surface of the trench 110. The first doped region 114 may be referred to as a “source region 114”, and the second doped region 115 may be referred to as a “drain region 115”. The buried gate structure BG may define a channel between the first doped region 114 and the second doped region 115. The channel may be defined along the profile of the trench 110.

The buried gate structure BG may be embedded in the trench 110. The buried gate structure BG may be disposed in the active region 103 between the first doped region 114 and the second doped region 115 and may extend into the isolation layer 102. The bottom surface of the portion of the buried gate structure BG disposed in the active region 103 and the bottom surface of the portion of the buried gate structure BG disposed in the isolation layer 102 may be disposed at different levels. When the fin 105 is omitted, the bottom surface of the portion of the buried gate structure BG disposed in the active region 103 and the bottom surface of the portion of the buried gate structure BG disposed in the isolation layer 102 may be disposed at the same level.

The buried gate structure BG may include a gate dielectric layer 111 that covers the semiconductor layer 304S and 304B formed on the bottom surface and inner sidewalls of the trench 110, a buried conductive layer 112 that fills the lower portion of the trench 110 over the gate dielectric layer 111, and a gate capping layer 113 that fills the upper portion of the trench 110 over the buried conductive layer 112.

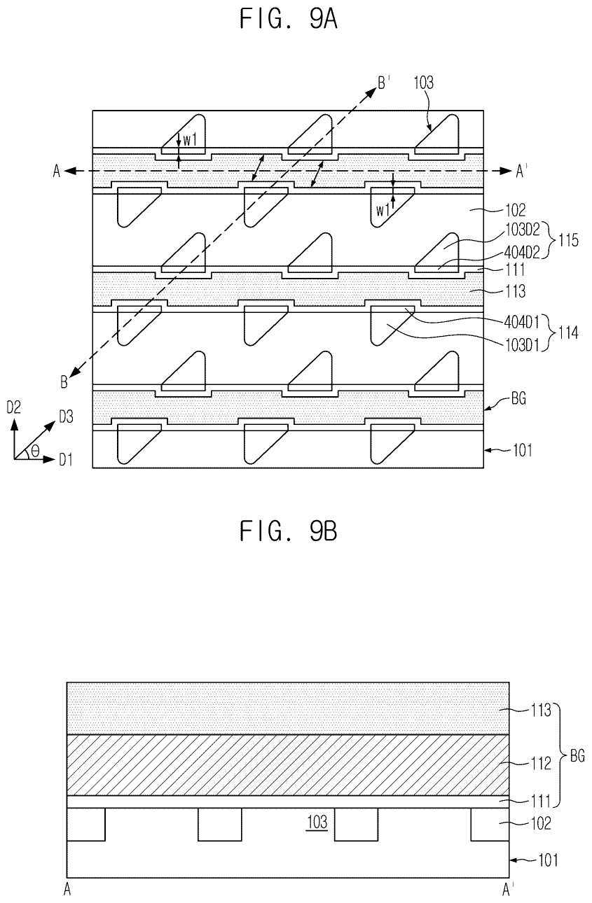

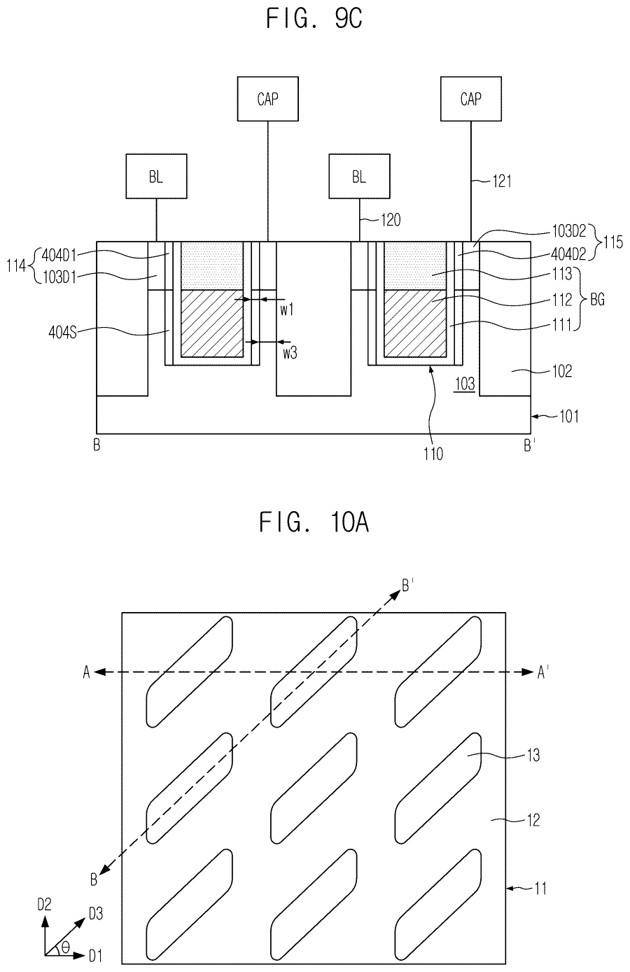

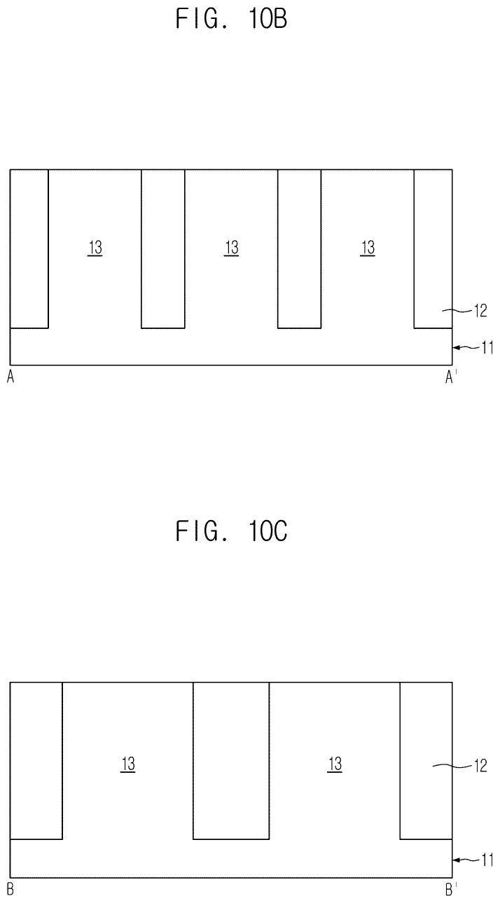

Referring to FIGS. 9A to 9C, the semiconductor device may include a substrate 101, and a buried gate structure BG, a first doped region 114, and a second doped region 115 that are embedded in the substrate 101. The buried gate structure BG and the first and second doped regions 114 and 115 may be (form) a cell transistor. With the buried gate structure, the cell transistor may be able to improve the short channel effect.

The semiconductor layer 404S may be selectively formed only on the inner sidewalls of the trench 110. In other words, the semiconductor layer may not be formed on the bottom surface of the trench 110, and the semiconductor layer 404S may be formed only on the inner sidewalls of the trench 110. A method for selectively forming the semiconductor layer 404S only on the inner sidewalls of the trench 110 will be described in detail below.

The first doped region 114 and the second doped region 115 may be formed in the active region 103. The first doped region 114 may be formed in the active region 103 and the semiconductor layer 404S on one side of the trench 110, and the second doped region 115 may be formed in the active region 103 and the semiconductor layer 404S on the other side of the trench 110. The first doped region 114 may include a first active doped region 103D1 and a first extended doped region 404D1. The second doped region 115 may include a second active doped region 103D2 and a second extended doped region 404D2. The first and second active doped regions 103D1 and 103D2 may refer to an active region 103 that is doped with an impurity. The first and second extended doped regions 404D1 and 404D2 may refer to the semiconductor layer 404S that is doped with an impurity.

According to this embodiment of the present disclosure, by additionally forming the semiconductor layer 404S on both sidewalls of the trench 110, the areas of the first and second doped regions 114 and 115 may be increased as much as the widths of the first and second extended doped regions 404D1 and 404D2. Accordingly, there is an effect of increasing the overlay margin between the substrate 101 and the upper structure (e.g., a bit line BL or a memory element CAP).

The first and second doped regions 114 and 115 may not be disposed on a straight line in the second direction D2. The first and second doped regions 114 and 115 may be disposed to be misaligned on the left and right in the second direction D2 so that there is no overlapping region.

The first doped region 114 and the second doped region 115 may be regions doped with conductive dopants. For example, the conductive dopant may include phosphorus (P), arsenic (As), antimony (Sb), or boron (B). The first doped region 114 and the second doped region 115 may be doped with dopants of the same conductivity type. The first doped region 114 and the second doped region 115 may be disposed in the active region 103 and the semiconductor layer 404S on both sides of the trench 110.

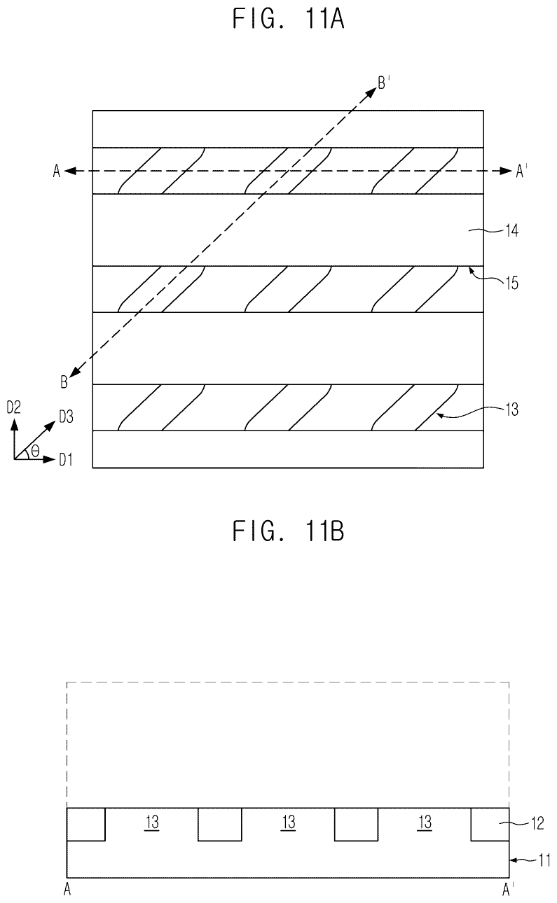

FIGS. 10A to 15C illustrate a method for fabricating a semiconductor device shown in FIG. 9A to 9C. FIGS. 10B, 11B, 12B, 13B 14B and 15B are process cross-sectional views taken along a line A-A′ shown in FIGS. 10A, 11A, 12A, 13A 14A and 15A. FIGS. 10C, 11C, 12C, 13C 14C and 15C are process cross-sectional views taken along a line B-B′ shown in FIGS. 10A, 11A, 12A, 13A 14A and 15A. FIGS. 10A to 15C may include a structure similar to the method for fabricating the semiconductor device illustrated in FIGS. 2A to 6C, except for the buried gate structure and the first and second doped regions. For the sake of convenience in description, description on the same structure may be briefly described or omitted.

Referring to FIGS. 10A to 10C, an isolation layer 12 may be formed in a substrate 11 to define active regions 13.

The substrate 11 may be a material suitable for semiconductor processing. The substrate 11 may include a semiconductor substrate. The substrate 11 may be formed of a material containing silicon.

The isolation layer 12 may be a shallow trench isolation region (STI) that is formed by a trench etching process. The isolation layer 12 may be formed by filling the isolation trench with a dielectric material. The isolation layer 12 may include silicon oxide, silicon nitride, or a combination thereof.

The active regions 13 may be formed of strips and may be arranged in the form of an array. The array of the active regions 13 may include a row array and/or a column array.

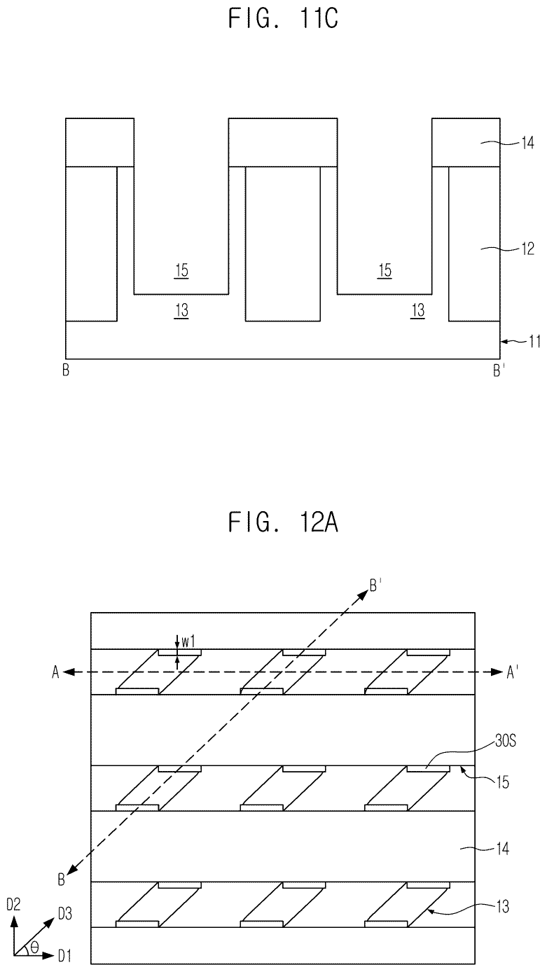

Referring to FIGS. 11A to 11C, a first hard mask layer 14 may be formed over the active regions 13 and the isolation layer 12.

The first hard mask layer 14 may have a line shape extending in the first direction D1 and disposed to be spaced apart from each other in the second direction D2. The first hard mask layer 14 may include a dielectric material having an etching selectivity with respect to the active regions 13 and the isolation layer 12. The first hard mask layer 14 may be formed in a single-layer structure or a stacked structure. The stacked structure of the first hard mask layer 14 may include dielectric materials having different etching selectivities.

Subsequently, a trench 15 extending in the first direction D1 may be formed by etching the active regions 13 and the isolation layer 12 with the first hard mask layer 14 used as an etching barrier.

One trench 15 may be formed in each active region 13. The trench 15 may cross the center of each active region 13. The trenches 15 may be disposed to be spaced apart from each other in the second direction D2. The trench 15 may have a shallower depth than the isolation layer 12. In other words, the bottom surface of the trench 15 may be disposed at a higher level than the bottom surface of the isolation layer 12. According to another embodiment of the present disclosure, the bottom portion of the trench 15 may have a curvature. The trench 15 may be a space where a buried gate structure is to be formed, and the trench 15 may be referred to as a “gate trench 15”.

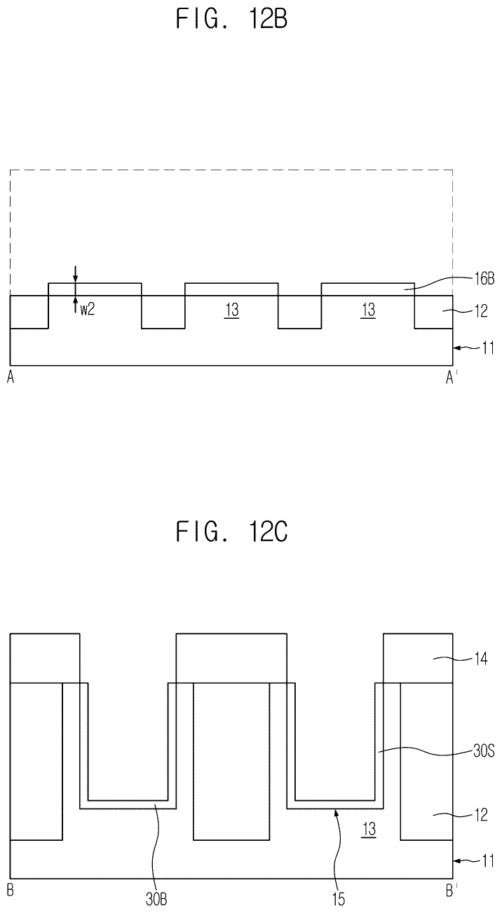

Referring to FIGS. 12A to 12C, the semiconductor layer 30S and 30B that covers the inner sidewalls and bottom surface of the trench 15 may be formed.

The semiconductor layer 30S and 30B may increase the volume of each active region 13. The semiconductor layer 30S and 30B may be selectively formed only in the trench 15 crossing each active region 13. The semiconductor layer 30S and 30B may not be formed over the isolation layer 12.

The semiconductor layer 30S and 30B may be formed by an epitaxial growth process. The epitaxial growth process may be a Selective Epitaxial Growth (SEG) process, and the semiconductor layer 30S and 30B may be selectively formed on the inner sidewalls and bottom surface of the active region 13 that is exposed by the trench 15.

The semiconductor layer 30S formed on the inner sidewalls of the trench 15 may have a first width w1. The semiconductor layer 30S formed on the inner sidewalls of the trench 15 may be formed to have the same first width w1 on both sides of the trench 15.

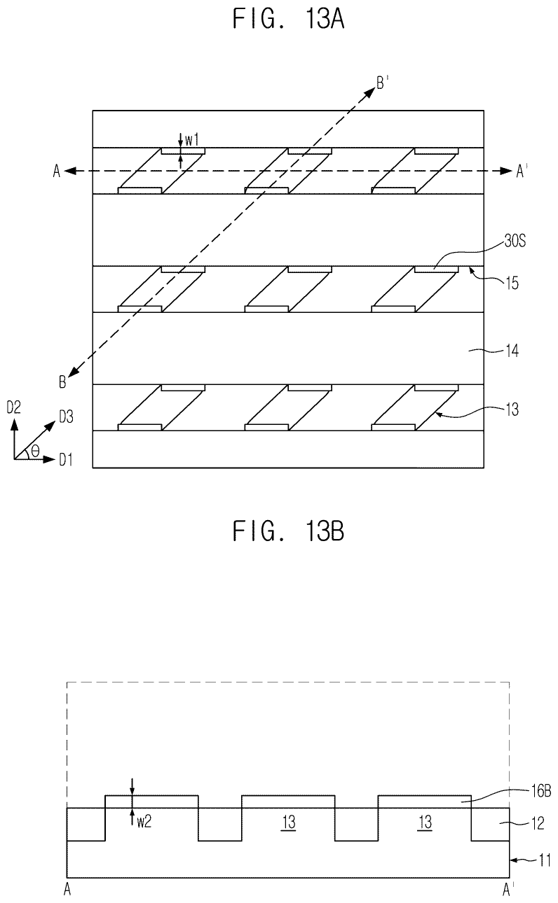

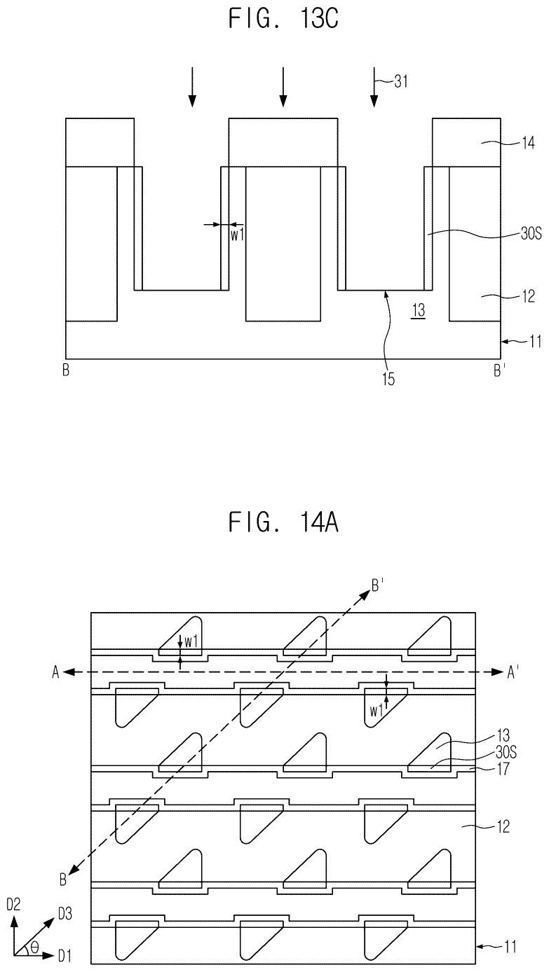

Referring to FIGS. 13A to 13C, the semiconductor layer (30B, see FIG. 12C) that covers the bottom surface of the trench 15 may be removed. The semiconductor layer 30B that covers the bottom surface of the trench 15 may be removed by a cleaning process 31.

This is because, since the bottom surface of the semiconductor layer is damaged a lot by being etched during the cleaning process, the cleaning process may have to be performed more strongly to remove the damaged layer compared to the sidewall.

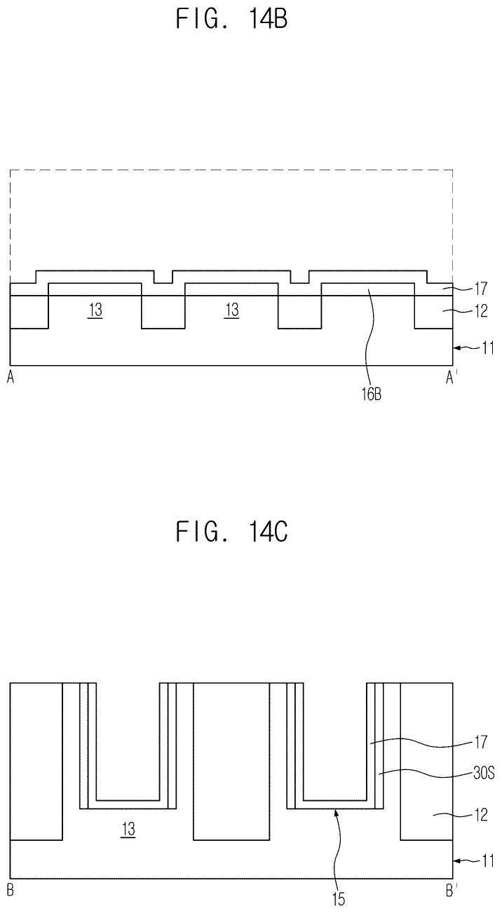

Referring to FIGS. 14A to 14C, a gate dielectric layer 17 that covers the inner surface of the trench 15 may be formed.

The gate dielectric layer 17 may be conformally formed on the bottom surface and inner sidewalls of the trench 15. Also, since the semiconductor layer 30S is formed on the bottom surface and inner sidewalls of the trench 15 crossing the active region 13, the gate dielectric layer 17 may uniformly cover the bottom surface and inner sidewalls of the trench 15 and the semiconductor layer 30S. The gate dielectric layer 17 may include silicon oxide, silicon nitride, silicon oxynitride, a high-k material, or a combination thereof. The high-k material may include a material having a dielectric constant which is greater than the dielectric constant of silicon oxide.

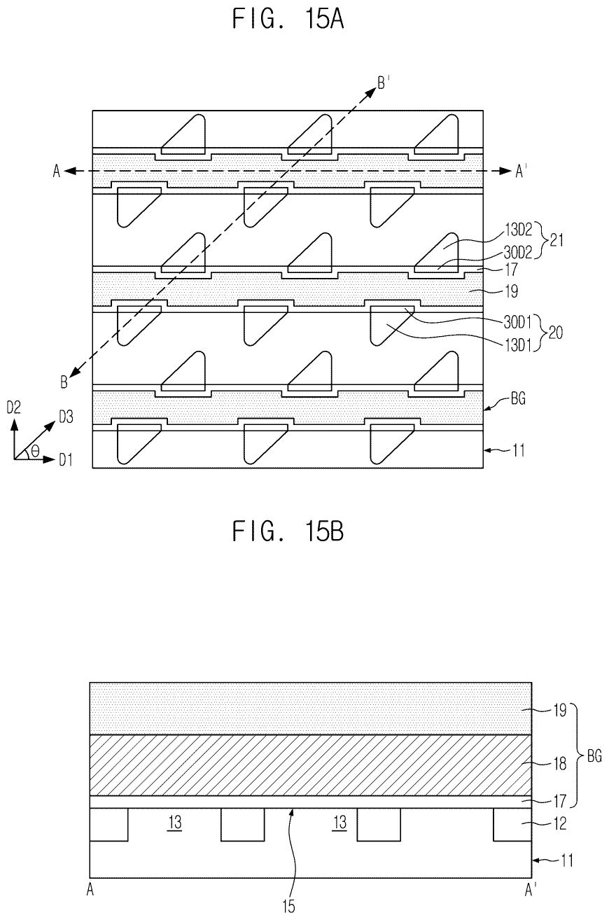

Referring to FIGS. 15A to 15C, a buried gate structure BG may be formed by sequentially stacking a buried conductive layer 18 and a gate capping layer 19 over a gate dielectric layer 17.

Subsequently, first and second doped regions 20 and 21 may be formed in the substrate 11 on both sides of the trench 15. The first doped region 20 may be formed in the active region 13 and the semiconductor layer 30S on one side of the trench 15, and the second doped region 21 may be formed in the active region 13 and the semiconductor layer 30S on the other side of the trench 15. The first doped region 20 may include a first active doped region 13D1 and a first extended doped region 30D1. The second doped region 21 may include a second active doped region 13D2 and a second extended doped region 30D2. The first and second active doped regions 13D1 and 13D2 may refer to an active region 13 that is doped with an impurity. The first and second extended doped regions 30D1 and 30D2 may refer to the semiconductor layer 30S that is doped with an impurity.

The buried gate structure BG may be formed by sequentially gap-filling the trench 15 with the gate dielectric layer 17, the buried conductive layer 18, and the gate capping layer 19. The buried gate structure BG may define a channel between the first doped region 20 and the second doped region 21. The channel may be defined along the profile of the trench 15.

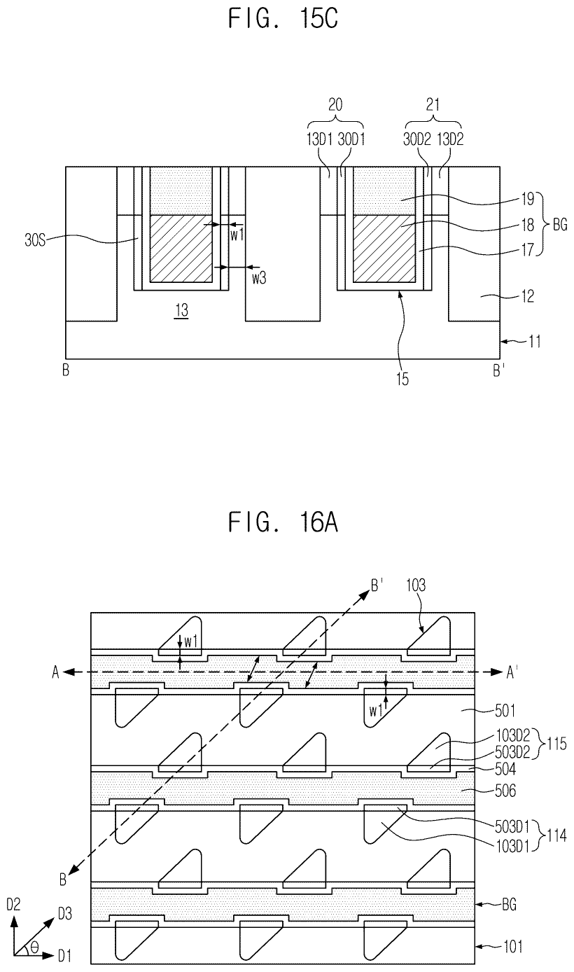

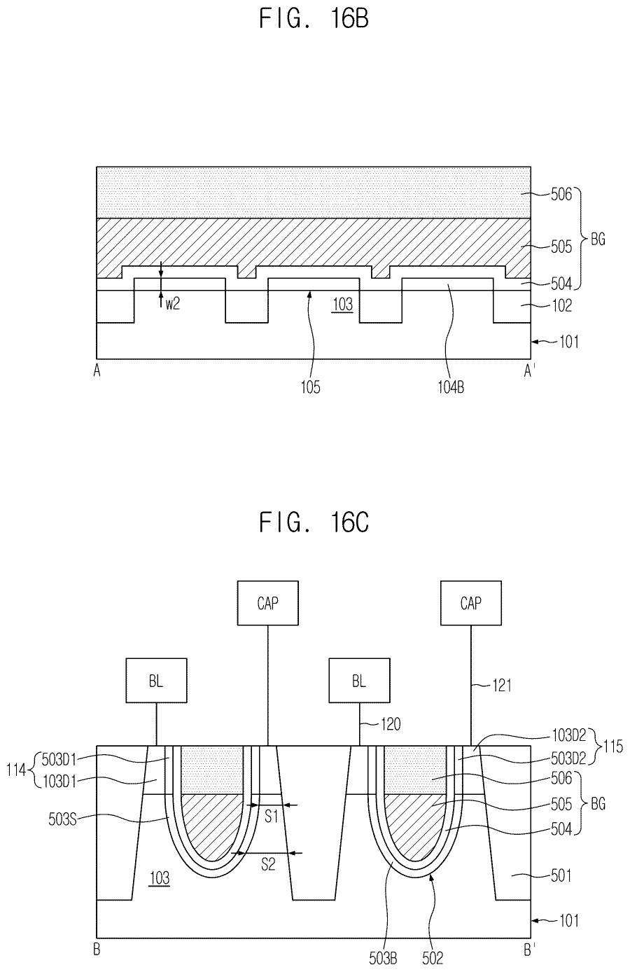

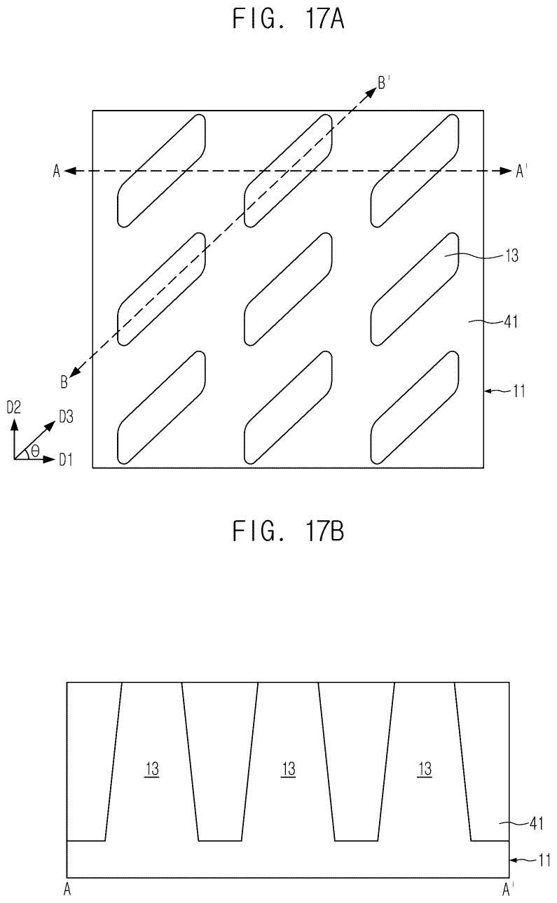

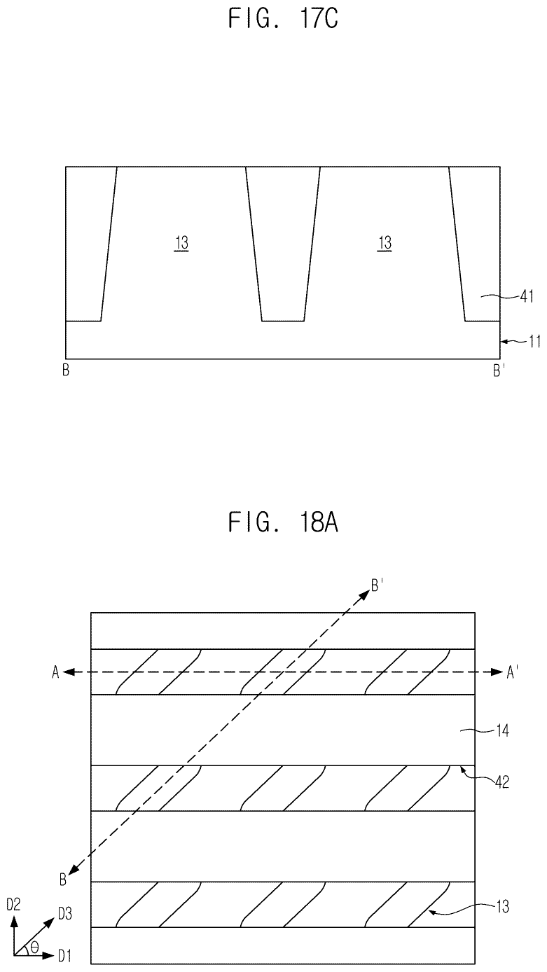

FIGS. 16A to 16C illustrate a semiconductor device in accordance with yet another example of the embodiment of the present disclosure. FIG. 16B is a cross-sectional view taken along a line A-A′ shown in FIG. 16A. FIG. 16C is a cross-sectional view taken along a line B-B′ shown in FIG. 16A. FIGS. 16A to 16C may include the same structure as the structure of FIGS. 1A to 1C except for the buried gate structure BG. For the sake of convenience in description, description on the same structure may be minimized or omitted.

Referring to FIGS. 16A to 16C, the semiconductor device may include a substrate 101, and a buried gate structure BG, a first doped region 114, and a second doped region 115 that are embedded in the substrate 101. The buried gate structure BG and the first and second doped regions 114 and 115 may be a cell transistor. With the buried gate structure, the cell transistor may be able to improve the short channel effect.

An isolation layer 501 and active regions 103 may be formed in the substrate 101. The active regions 103 may be defined by the isolation layer 501. The isolation layer 501 may be a shallow trench isolation region (STI) formed by a trench etching process. The isolation layer 501 may be formed with an inclined side. The isolation layer 501 may have a width that gradually decreases as it goes away from the surface of the substrate 101. The isolation layer 501 may be formed by filling a shallow trench, for example, an isolation trench, with a dielectric material. The isolation layer 501 may include silicon oxide, silicon nitride, or a combination thereof.

The active regions 103 may be formed of strips and may be arranged in the form of an array. The array of the active regions 103 may include a row array and/or a column array. The row array of the active regions 103 may include active regions 103 that are arranged in the first direction D1. The column array of the active regions 103 may include active regions 103 that are arranged in the second direction D2 which is orthogonal to the first direction D1.

Each active region 103 may have a long axis and a short axis. The long axis direction of each active region 103 may be referred to as a “longitudinal direction of each active region 103”. The short axis direction of each active region 103 may be referred to as a “width direction of each active region 103”. The longitudinal direction of the active regions 103, i.e., the third direction D3, may be non-orthogonal to the first direction D1 and the second direction D2 to form an intersection angle θ. The intersection angle θ between the first direction D1 and the third direction D3 of each active region 103 may range from approximately 10° to 80°, but the concept and spirit of the embodiment of the present disclosure are not limited thereto. The range of the intersection angle θ may be affected by such parameters as the area of each active region 103, the line width of the bit line, and the line width of the buried gate structure BG. Each active region 103 may be a parallelogram, for example, a parallelogram including rounded edges.

The active regions 103 may be arranged in the third direction D3.

A trench 502 may be formed in the substrate 101. Referring to FIG. 16A, the trench 502 may have a line shape extending in the first direction D1. The trench 502 may be a line shape that crosses the active regions 103 and the isolation layer 501. One trench 502 may be formed in each active region 103. The trench 502 may cross the center of each of the active regions 103 that are arranged in the first direction D1.

The trenches 502 may be disposed spaced apart from each other in the second direction D2. The trench 502 may have a shallower depth than the isolation layer 501. In other words, the bottom surface of the trench 502 may be disposed at a higher level than the bottom surface of the isolation layer 501. The bottom surface of the trench 502 may be formed in a curved shape. The trench 502 may have a ‘U’ shape. The trench 502 may be a space where the buried gate structure BG is to be formed, and the trench 502 may be referred to as a “gate trench 502”.

The distance between the inner sidewalls of the trench 502 and the isolation layer 501 may vary according to the depth. In other words, since the bottom surface of the trench 502 is formed as a curved surface and the isolation layer 501 has a side slope, the distance between the inner sidewalls of the trench 502 and the isolation layer 501 may become longer as it gets farther from the top surface of the substrate 101. When the distance between the inner sidewall of the middle portion of the trench 502 and the isolation layer 501 is referred to as S1 and the distance between the inner sidewall close to the bottom surface of the trench 502 and the isolation layer 501 is referred to as S2, the width of S2 may be larger than the width of S1. When the distance between the inner sidewall close to the bottom surface of the trench 501 and the isolation layer 501 is sufficient, the semiconductor layer on the bottom surface of the trench 501 may be omitted.

The semiconductor layer 503S and 503B may be formed along the profile of the inner sidewalls and bottom surface of the trench 502. The semiconductor layer 503S and 503B may serve to increase the volume of each active region 103. The semiconductor layer 503S and 503B may be selectively formed only in the trench 502 crossing each active region 103. The semiconductor layer 503S and 503B may not be formed over the isolation layer 501. A portion of the semiconductor layer 503S that covers the inner sidewalls of the trench 502 may be a doped region. The semiconductor layer 503B that covers the bottom surface of the trench 502 may serve as the fin 105 or a portion of the fin 105.

The semiconductor layer 503S and 503B may be formed by an epitaxial growth process. The epitaxial growth process may include a Selective Epitaxial Growth (SEG) process. The semiconductor layer 503S and 503B may be selectively formed on the inner sidewalls and bottom surface of the active region 103 that is exposed by the trench 502.

According to the embodiment of the present disclosure, by forming the semiconductor layer 503S on the inner sidewalls of the trench 502, the width of the active region 103 may expand as much as the width of the semiconductor layer 503S formed on the inner sidewalls of the trench 502.

In particular, in case of a Dynamic Random Access Memory (DRAM) of approximately 10 nm Tech or less, the third width W3 may become narrower as semiconductors are integrated, and thus, it may enter a region where the quantum mechanical mobility decreases. However, according to this embodiment of the present disclosure, it is possible to prevent the mobility from decreasing by securing the reduced width of the active region through the semiconductor layer 503S and 503B.

Referring to FIG. 16B, the height difference between the bottom surface of the trench 502 crossing the isolation layer 501 and the bottom surface of the trench 502 crossing the active region 103 may be the width of the semiconductor layer 503B on the bottom surface of the trench 502. Therefore, the semiconductor layer 503B on the bottom surface of the trench 502 may function as the fin 105. The fin 105 may be referred to as a saddle fin. The fin 105 may increase the channel width and improve the electrical characteristics.

According to another embodiment of the present disclosure, the bottom surface of the trench 502 crossing the isolation layer 501 may be additionally etched to further increase the height of the fin 105.

The first doped region 114 and the second doped region 115 may be formed in the active region 103. The first doped region 114 may be formed in the active region 103 and the semiconductor layer 503S on one side of the trench 502, and the second doped region 115 may be formed in the active region 103 and the semiconductor layer 503S on the other side of the trench 110. The first doped region 114 may include a first active doped region 103D1 and a first extended doped region 503D1. The second doped region 115 may include a second active doped region 103D2 and a second extended doped region 503D2. The first and second active doped regions 103D1 and 103D2 may refer to an active region 103 that is doped with an impurity. The first and second extended doped regions 503D1 and 503D2 may refer to the semiconductor layer 503S that is doped with an impurity.

According to this embodiment of the present disclosure, by additionally forming the semiconductor layer 503S on both sidewalls of the trench 503, the areas of the first and second doped regions 114 and 115 may be increased as much as the widths of the first and second extended doped regions 503D1 and 503D2. Accordingly, there is an effect of increasing the overlay margin between the substrate 101 and the upper structure (e.g., a bit line BL or a memory element CAP).

The first and second doped regions 114 and 115 may not be disposed on a straight line in the second direction D2. The first and second doped regions 114 and 115 may be disposed to be misaligned on the left and right in the second direction D2 so that there is no overlapping region.

The first doped region 114 and the second doped region 115 may be regions doped with conductive dopants. For example, the conductive dopant may include phosphorus (P), arsenic (As), antimony (Sb), or boron (B). The first doped region 114 and the second doped region 115 may be doped with dopants of the same conductivity type. The first doped region 114 and the second doped region 115 may be disposed in the active region 103 and the semiconductor layer 503S on both sides of the trench 502. The bottom surfaces of the first doped region 114 and the second doped region 115 may be higher than the bottom surface of the trench 502. The buried gate structure BG may define a channel between the first doped region 114 and the second doped region 115. The channel may be defined along the profile of the trench 502.

The buried gate structure BG may be embedded in the trench 502. The buried gate structure BG may be disposed in the active region 103 between the first doped region 114 and the second doped region 115 and may extend into the isolation layer 501. The bottom surface of the portion of the buried gate structure BG disposed in the active region 103 and the bottom surface of the portion of the buried gate structure BG disposed in the isolation layer 501 may be disposed at different levels. When the fin 105 is omitted, the bottom surface of the portion of the buried gate structure BG disposed in the active region 103 and the bottom surface of the portion of the buried gate structure BG disposed in the isolation layer 501 may be disposed at the same level.

The buried gate structure BG may include a gate dielectric layer 504 that covers the semiconductor layer 503S and 503B formed on the bottom surface and inner sidewalls of the trench 502, a buried conductive layer 505 that fills the lower portion of the trench 502 over the gate dielectric layer 504, and a gate capping layer 506 that fills the upper portion of the trench 502 over the buried conductive layer 505.

The gate dielectric layer 504 may be formed over the semiconductor layer 503S and 503B. The gate dielectric layer 504 may be formed conformally along the surface of the semiconductor layer 503S and 503B. The gate dielectric layer 504 may include silicon oxide, silicon nitride, silicon oxynitride, a high-k material, or a combination thereof. The high-k material may include a material having a dielectric constant which is greater than the dielectric constant of silicon oxide.

The buried conductive layer 505 may fill a portion of the trench 502. The buried conductive layer 505 in the trench 502 may be formed in a wavy line shape extending in the first direction D1 by the semiconductor layer 503S. The buried conductive layer 505 may be referred to as a ‘gate electrode 505’. The buried conductive layer 505 may be a low-resistance material to lower the gate sheet resistance. The buried conductive layer 505 may include a semiconductor material, a metal-based material, or a combination thereof. The buried conductive layer 505 may include polysilicon, a metal, a metal nitride, or a combination thereof. For example, the buried conductive layer 505 may include N-type doped polysilicon, tantalum nitride (TaN), titanium nitride (TiN), tungsten (W), tungsten nitride (WN), molybdenum (Mo), ruthenium (Ru), or a combination thereof. According to another embodiment of the present disclosure, the buried conductive layer 112 may be formed of titanium nitride alone or molybdenum alone. According to yet another embodiment of the present disclosure, the buried conductive layer 505 may be formed of a stack of titanium nitride and tungsten (i.e., TiN/W) or a stack of titanium nitride and polysilicon (i.e., TiN/Polysilicon).

According to another embodiment of the present disclosure, the buried conductive layer 505 may apply a dual gate structure including upper and lower gates. According to yet another embodiment of the present disclosure, the buried conductive layer 505 may apply a triple gate structure including upper, middle, and lower gates.

According to another embodiment of the present disclosure, the buried conductive layer 505 may have a high work function. For example, the buried conductive layer 505 may include P-type polysilicon or nitrogen-rich titanium nitride.

According to another embodiment of the present disclosure, the buried conductive layer 505 may have an increased high work function. The buried conductive layer 505 may include a metal silicon nitride. The metal silicon nitride may be a metal nitride that is doped with silicon. The buried conductive layer 505 may include a metal silicon nitride having a controlled silicon content. For example, the buried conductive layer 505 may include tantalum silicon nitride (TaSiN) or titanium silicon nitride (TiSiN). Titanium nitride may have a high work function, and silicon may be added to titanium nitride to further increase the work function of the titanium nitride. The titanium silicon nitride may have a controlled silicon content to have an increased high work function. According to another embodiment of the present disclosure, the buried conductive layer 505 may include titanium aluminum nitride (TiAlN).

A gate capping layer 506 may be formed over the buried conductive layer 505. The gate capping layer 506 may prevent the buried conductive layer 505 from being oxidized. The gate capping layer 506 may be formed in the trench 502 to electrically insulate the upper structure such as a contact, a conductive line and the like, from the buried conductive layer 505. According to one embodiment of the present disclosure, the top surface of the gate capping layer 506 may be disposed at the same level as the top surface of the substrate 101.

The gate capping layer 506 may include a dielectric material. The gate capping layer 506 may include silicon nitride or silicon oxide, but the concept and spirit of the present disclosure are not limited thereto. According to another embodiment of the present disclosure, the gate capping layer 506 may include a low-k material. The gate capping layer 506 may be formed as a single layer. According to another embodiment of the present disclosure, the gate capping layer 506 may be formed as a multi-layer structure of different materials.

As described above, the embodiment of the present disclosure may increase the widths of the first and second doped regions 114 and 115 by forming the semiconductor layer 503S on the inner sidewalls of the trench 502 crossing the active region 103. Also, since the semiconductor layer 503S formed on one sidewalls of the trench 502 and the semiconductor layer 503S formed on the other sidewalls of the trench 502 are not disposed on a straight line in the second direction D2, the reduction of the line width of the trench 502 due to the semiconductor layer 503S may be minimized. After all, since the reduction in the volume of the buried conductive layer 505 buried in the trench 502 may be minimized, the increase in the resistance of the semiconductor device may be minimized.

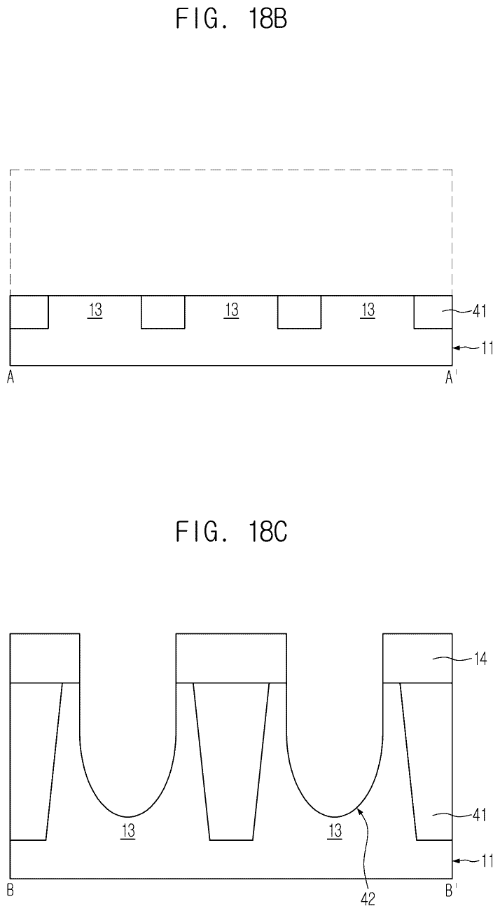

FIGS. 17A to 21C illustrate a method for fabricating the semiconductor device shown in FIGS. 16A to 16C. FIGS. 17B, 18B, 19B, 20B and 21B are process cross-sectional views taken along a line A-A′ shown in FIGS. 17A, 18A, 19A, 20A and 21A. FIGS. 17C, 18C, 19C, 20C and 21C are process cross-sectional views taken along a line B-B′ shown in FIGS. 17A, 18A, 19A, 20A and 21A. FIGS. 17A to 21C may include a structure similar to the semiconductor device illustrated in FIGS. 2A to 6C, except for the buried gate structure and the first and second doped regions. For the sake of convenience in description, description on the same structure may be briefly described or omitted.

Referring to FIGS. 17A to 17C, an isolation layer 41 may be formed over a substrate 11 to define active regions 13.

The substrate 11 may be a material suitable for semiconductor processing. The substrate 11 may include a semiconductor substrate. The substrate 11 may be formed of a material containing silicon.

The isolation layer 41 may be a shallow trench isolation region (STI) that is formed by a trench etching process. The isolation layer 41 may be formed to have an inclined side. The isolation layer 41 may have a width that gradually decreases as it goes away from the surface of the substrate 101. The isolation layer 41 may be formed by filling an isolation trench with a dielectric material. The isolation layer 41 may include silicon oxide, silicon nitride, or a combination thereof.

The active regions 13 may be formed of strips and may be arranged in the form of an array. The array of the active regions 13 may include a row array and/or a column array. The row array of the active regions 13 may include active regions 13 that are arranged in the first direction D1. The column array of the active regions 13 may include active regions 13 that are arranged in the second direction D2 which is orthogonal to the first direction D1. The longitudinal direction of the active regions 13, i.e., the third direction D3, may be non-orthogonal to the first direction D1 and the second direction D2 to form an intersection angle θ. The intersection angle θ between the first direction D1 and the third direction D3 of each active region 13 may range from approximately 10° to 80°, but the concept and spirit of the embodiment of the present disclosure are not limited thereto. The range of the intersection angle θ may be affected by such parameters as the area of each active region 13, the line width of the bit line, and the line width of the buried gate structure.

The active regions 13 may be arranged in the third direction D3.

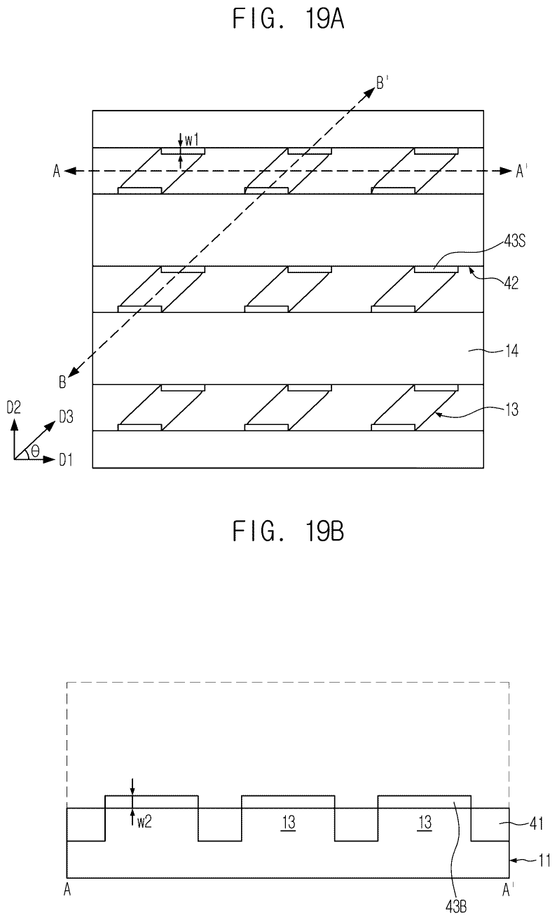

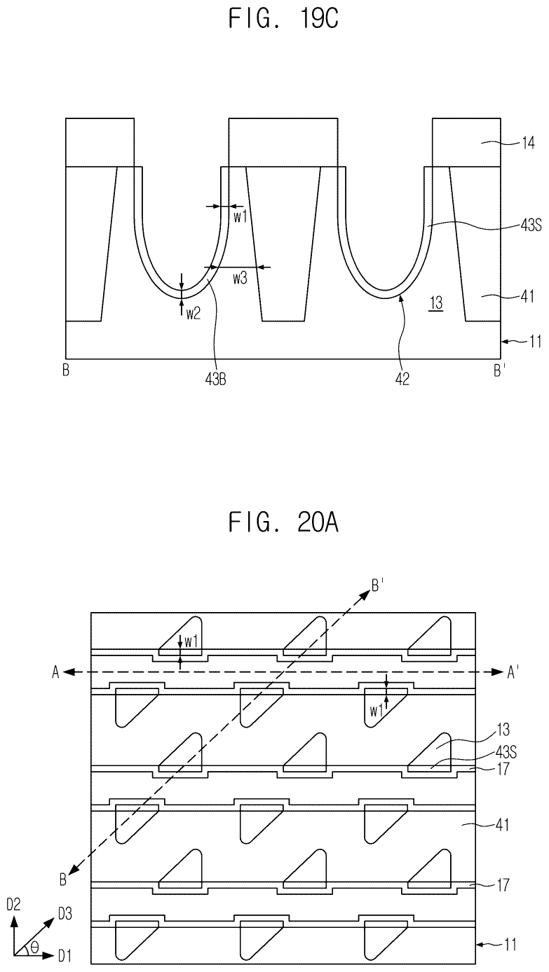

Referring to FIGS. 18A to 18C, a first hard mask layer 14 may be formed over the active regions 13 and the isolation layer 41.

The first hard mask layer 14 may have a line shape extending in the first direction D1 and spaced apart in the second direction D2. The first hard mask layer 14 may include a dielectric material having an etching selectivity with respect to the active regions 13 and the isolation layer 41. The first hard mask layer 14 may be formed in a single-layer structure or a stacked structure. The stacked structure of the first hard mask layer 14 may include dielectric materials having different etching selectivities.

Subsequently, a trench 42 extending in the first direction D1 may be formed by etching the active regions 13 and the isolation layer 41 with the first hard mask layer 14 used as an etching barrier to form.

One trench 42 may be formed in each active region 13. The trench 42 may cross the center of each active region 13. The trenches 42 may be disposed to be spaced apart from each other in the second direction D2. The trench 42 may have a shallower depth than the isolation layer 12. In other words, the bottom surface of the trench 42 may be disposed at a higher level than the bottom surface of the isolation layer 41. The bottom portion of the trench 42 may have a curvature. The trench 42 may be a space where a buried gate structure is to be formed, and the trench 42 may be referred to as a “gate trench 42”.

Referring to FIGS. 19A to 19C, a semiconductor layer 43S and 43B that covers the inner sidewalls and bottom surface of the trench 42 may be formed.

The semiconductor layer 43S and 43B may increase the volume of each active region 13. The semiconductor layer 43S and 43B may be selectively formed only in the trench 42 crossing each active region 13. The semiconductor layer 43S and 43B may not be formed over the isolation layer 41. A portion of the semiconductor layer 43S that covers the inner sidewalls of the trench 42 may be a doped region. The semiconductor layer 43B that covers the bottom surface of the trench 42 may serve as a fin or a portion of the fin.

The semiconductor layer 43S and 43B may be formed by an epitaxial growth process. The epitaxial growth process may be a Selective Epitaxial Growth (SEG) process, and the semiconductor layer 43S and 43B may be selectively formed on the inner sidewalls and bottom surface of the active region 13 that is exposed by the trench 15.

The semiconductor layer 43S formed on the inner sidewalls of the trench 42 may have a first width W1, and the semiconductor layer 43B formed on the bottom surface of the trench 42 may have a second width W2. The first width W1 and the second width W2 may have the same thickness. The semiconductor layer 43S formed on the inner sidewalls of the trench 42 may be formed to have the same first width W1 on both sides of the trench 42.

Referring to FIG. 19C, the active region 13 between one sidewall of the trench 42 and the isolation layer 41 may have a third width W3. The third width W3 may be wider than the first width W1 and the second width W2, but the concept and spirit of the present disclosure are not limited thereto. According to the embodiment of the present disclosure, by forming the semiconductor layer 43S on the inner sidewalls of the trench 42, the width of the active region 13 may be substantially represented by the sum of the first width W1 and the third width W3. In other words, the width of the active region 13 may expand as much as the first width W1 of the semiconductor layer 43S that is formed on the inner sidewalls of the trench 42.

Referring to FIG. 19B, the height difference between the bottom surface of the trench 42 crossing the isolation layer 41 and the bottom surface of the trench 42 crossing the active region 13 may be the second width W2 of the semiconductor layer 43B on the bottom surface of the trench 42. Therefore, the semiconductor layer 43B on the bottom surface of the trench 42 may function as a fin. The fin may be referred to as a saddle fin. The fin may increase the channel width and improve the electrical characteristics.

According to another embodiment of the present disclosure, the semiconductor layer 43B on the bottom surface of the trench 42 may be omitted. According to yet another embodiment of the present disclosure, the bottom surface of the trench 42 crossing the isolation layer 41 may be additionally etched to further increase the height of the fin.

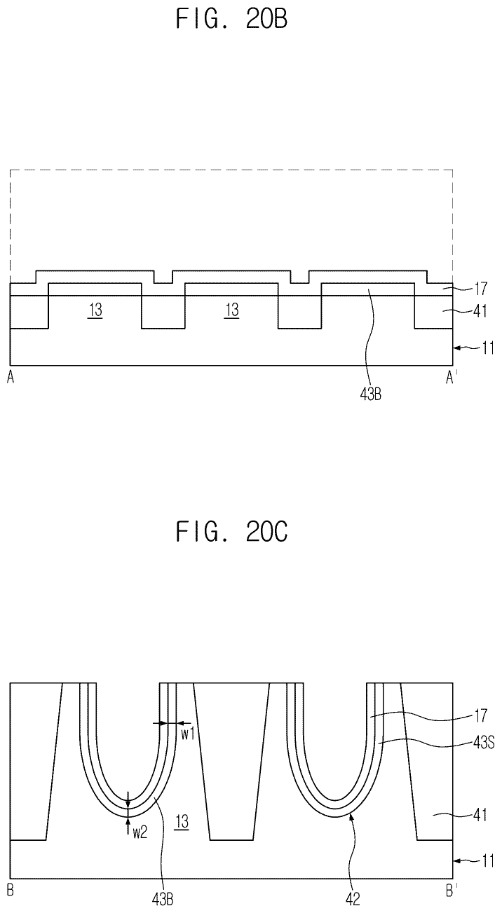

Referring to FIGS. 20A to 20C, a gate dielectric layer 17 that covers the inner surface of the trench 42 may be formed.

The gate dielectric layer 17 may be conformally formed on the bottom surface and inner sidewalls of the trench 42. Also, since the semiconductor layer 43S and 43B is formed on the bottom surface and inner sidewalls of the trench 42 crossing the active region 13, the gate dielectric layer 17 may uniformly cover the semiconductor layer 43S on the bottom surface and inner sidewalls of the trench 42. The gate dielectric layer 17 may include silicon oxide, silicon nitride, silicon oxynitride, a high-k material, or a combination thereof. The high-k material may include a material having a dielectric constant which is greater than the dielectric constant of silicon oxide.

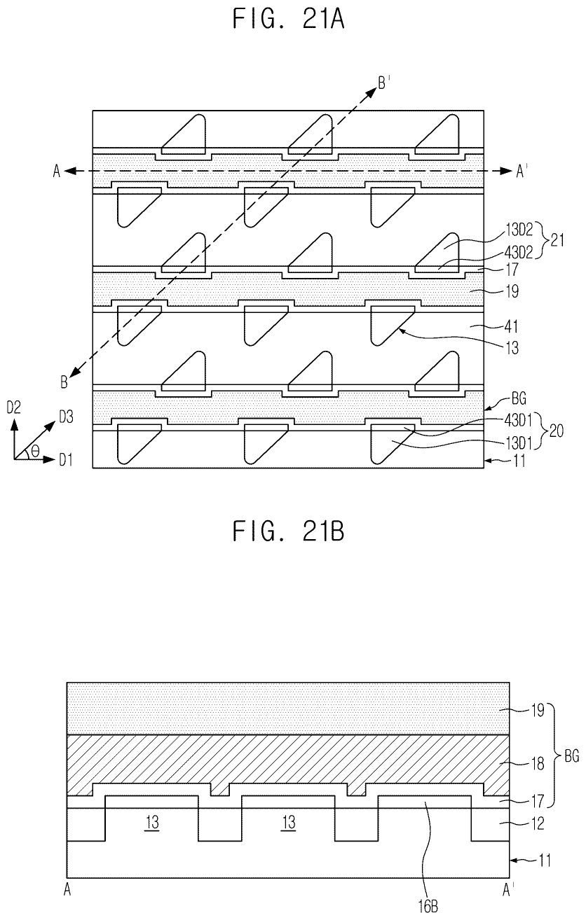

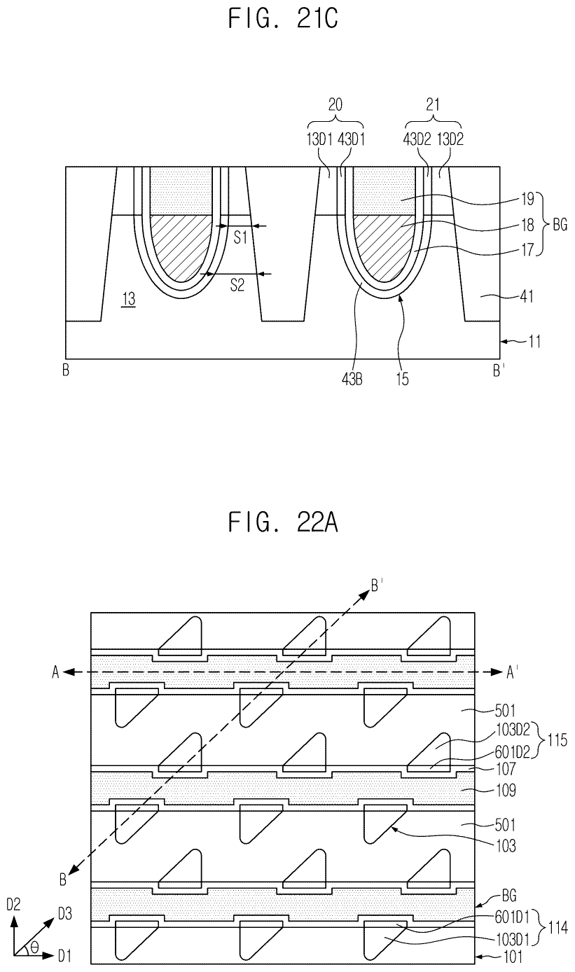

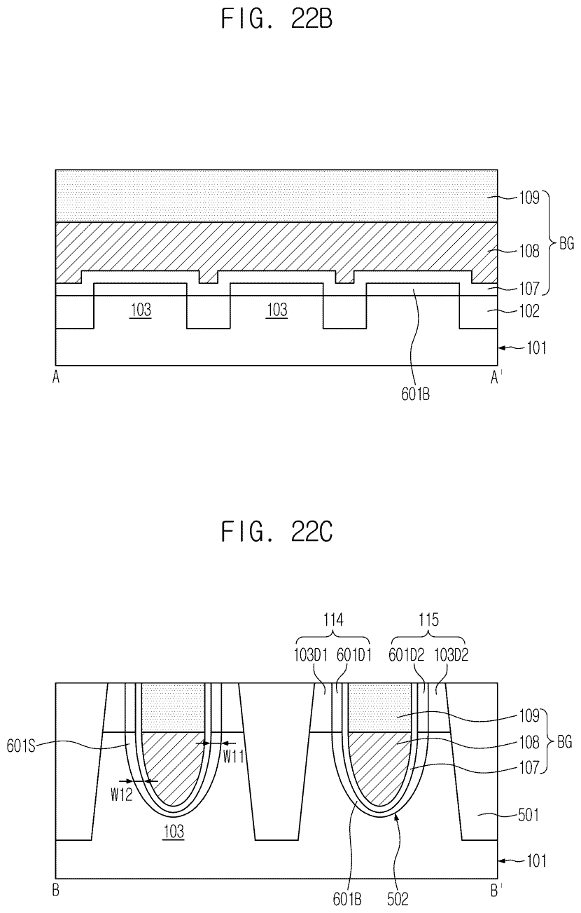

Referring to FIGS. 21A to 21C, a buried gate structure BG may be formed by sequentially stacking a buried conductive layer 18 and a gate capping layer 19 over the gate dielectric layer 17.

Subsequently, first and second doped regions 20 and 21 may be formed in the substrate 11 on both sides of the trench 42. The first doped region 20 may be formed in the active region 13 and the semiconductor layer 43S on one side of the trench 42, and the second doped region 21 may be formed in the active region 13 and the semiconductor layer 43S on the other side of the trench 42. The first doped region 20 may include a first active doped region 13D1 and a first extended doped region 43D1. The second doped region 21 may include a second active doped region 13D2 and a second extended doped region 43D2. The first and second active doped regions 13D1 and 13D2 may refer to an active region 13 that is doped with an impurity. The first and second extended doped regions 43D1 and 43D2 may refer to the semiconductor layer 43S that is doped with an impurity.

The buried gate structure BG may be formed by sequentially gap-filling the trench 42 with the gate dielectric layer 17, the buried conductive layer 18, and the gate capping layer 19. The buried gate structure BG may define a channel between the first doped region 20 and the second doped region 21. The channel may be defined along the profile of the trench 15.

FIGS. 22A to 24C illustrate a semiconductor device in accordance with other examples of the embodiment of the present disclosure. FIGS. 22B, 23B and 24B are process cross-sectional views taken along a line A-A′ shown in FIGS. 22A, 23A and 24A. FIGS. 22C, 23C and 24C are process cross-sectional views taken along a line B-B′ shown in FIGS. 22A, 23A and 24A. FIGS. 22A to 24C may include the same structure as those of FIGS. 16A to 16C except for the buried gate structure BG and the first and second doped regions 114 and 115. For the sake of convenience in description, description on the same structure may be minimized or omitted.

Referring to FIGS. 22A to 22C, the semiconductor device may include a substrate 101, and a buried gate structure BG, a first doped region 114, and a second doped region 115 that are embedded in the substrate 101. The buried gate structure BG and the first and second doped regions 114 and 115 may be a cell transistor. With the buried gate structure, the cell transistor may be able to improve the short channel effect.

An isolation layer 102 and active regions 103 may be formed in the substrate 101. The active regions 103 may be defined by the isolation layer 501.

A trench 502 may be formed in the substrate 101.

A semiconductor layer 601S and 601B may be formed along the profile of the inner sidewalls and bottom surface of the trench 502. The semiconductor layer 601S and 601B may serve to increase the volume of each active region 103. The semiconductor layer 601S and 601B may be selectively formed only in the trench 502 crossing each active region 103. The semiconductor layer 601S and 601B may not be formed over the isolation layer 501. A portion of the semiconductor layer 601S that covers the inner sidewalls of the trench 502 may be a doped region. The semiconductor layer 601B that covers the bottom surface of the trench 502 may serve as the fin 105 or a portion of the fin 105.

The semiconductor layer 601S and 601B may be formed by an epitaxial growth process. The epitaxial growth process may include a Selective Epitaxial Growth (SEG) process. The semiconductor layer 601S and 601B may be selectively formed on the inner sidewalls and bottom surface of the active region 103 that is exposed by the trench 502.

The semiconductor layer 601S formed on the inner sidewalls of the trench 502 may have a first width W1, and the semiconductor layer 601B formed on the bottom surface of the trench 502 may have a second width W2.

The semiconductor layer 601S formed on the inner sidewalls of the trench 502 may have different thicknesses on both sidewalls of the trench 502. In other words, the thickness of the first side width W11 of the semiconductor layer 601S formed on one sidewall of the trench 502 and the thickness of the second side width W12 of the semiconductor layer 601S formed on the other sidewall of the trench 502 may be different from each other. The first side width W11 may be smaller than the second side width W12.

Accordingly, the width of the first doped region 114 may be larger than the width of the second doped region 115.

According to another embodiment of the present disclosure, the first side width W11 may be larger than the second side width W12. The width of the first doped region 114 may be smaller than the width of the second doped region 115.

Referring to FIG. 22B, the height difference between the bottom surface of the trench 502 crossing the isolation layer 501 and the bottom surface of the trench 502 crossing the active region 103 may be the second width W2 of the semiconductor layer 601B on the bottom surface of the trench 502. Therefore, the semiconductor layer 601B on the bottom surface of the trench 502 may function as a fin. The fin may be referred to as a saddle fin. The fin may increase the channel width and improve the electrical characteristics.

According to another embodiment of the present disclosure, the height of the fin may be further increased by additionally etching the bottom surface of the trench 502 crossing the isolation layer 501.

The first doped region 114 and the second doped region 115 may be formed in the active region 103. The first doped region 114 may be formed in the active region 103 and the semiconductor layer 601S on one side of the trench 110, and the second doped region 115 may be formed in the active region 103 and the semiconductor layer 601S on the other side of the trench 110. The first doped region 114 may include a first active doped region 103D1 and a first extended doped region 601D1. The second doped region 115 may include a second active doped region 103D2 and a second extended doped region 601D2. The first and second active doped regions 103D1 and 103D2 may refer to an active region 103 that is doped with an impurity. The first and second extended doped regions 601D1 and 601D2 may refer to the semiconductor layer 601S that is doped with an impurity.

According to the embodiment of the present disclosure, the areas of the first and second doped regions 114 and 115 may be increased as much as the widths of the first and second extended doped regions 601D1 and 601D2 by additionally forming the semiconductor layer 601S on both sidewalls of the trench 502. Accordingly, there is an effect of increasing the overlay margin between the substrate 101 and the upper structure (e.g., a bit line BL or a memory element CAP).

The first and second doped regions 114 and 115 may not be disposed on a straight line in the second direction D2. The first and second doped regions 114 and 115 may be disposed to be misaligned on the left and right in the second direction D2 so that there may be no overlapping region.

The first doped region 114 and the second doped region 115 may be regions doped with conductive dopants. For example, the conductive dopant may include phosphorus (P), arsenic (As), antimony (Sb), or boron (B). The first doped region 114 and the second doped region 115 may be doped with dopants of the same conductivity type. The first doped region 114 and the second doped region 115 may be disposed in the active region 103 and the semiconductor layer 601S on both sides of the trench 502.

The buried gate structure BG may be embedded in the trench 502. The buried gate structure BG may be disposed in the active region 103 between the first doped region 114 and the second doped region 115 and may extend into the isolation layer 501. The bottom surface of the portion of the buried gate structure BG disposed in the active region 103 and the bottom surface of the portion of the buried gate structure BG disposed in the isolation layer 501 may be disposed at different levels. When the fin is omitted, the bottom surface of the portion of the buried gate structure BG disposed in the active region 103 and the bottom surface of the portion of the buried gate structure BG disposed in the isolation layer 501 may be disposed at the same level.

The buried gate structure BG may include a gate dielectric layer 111 that covers the semiconductor layer 601S and 601B formed on the bottom surface and inner sidewalls of the trench 502, a buried conductive layer 112 that fills the lower portion of the trench 502 over the gate dielectric layer 111, and a gate capping layer 113 that fills the upper portion of the trench 502 over the buried conductive layer 112.

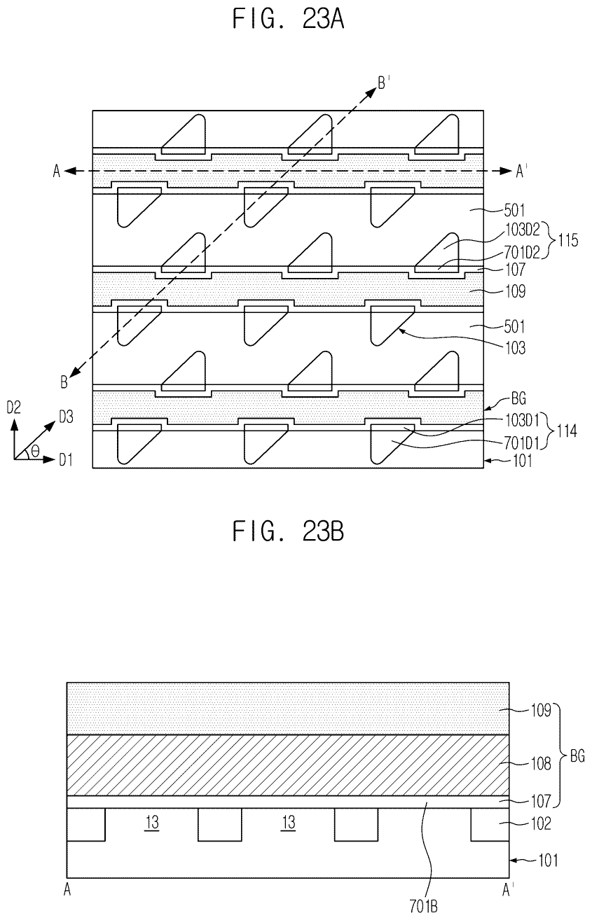

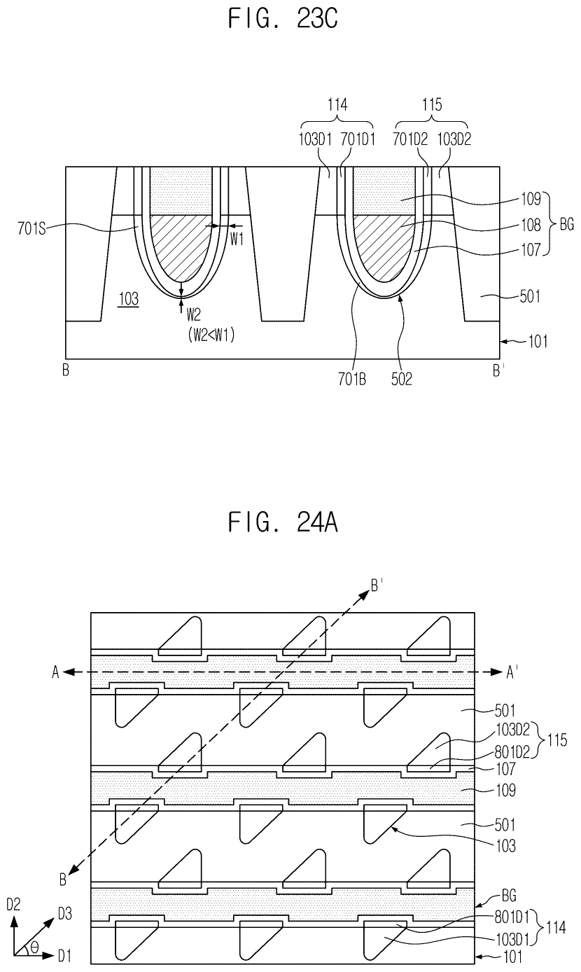

Referring to FIGS. 23A to 23C, the semiconductor device may include a substrate 101, and a buried gate structure BG, a first doped region 114, and a second doped region 115 that are embedded in the substrate 101. The buried gate structure BG and the first and second doped regions 114 and 115 may be a cell transistor. With the buried gate structure, the cell transistor may be able to improve the short channel effect.

A semiconductor layer 701S and 701B may be formed along the profile of the inner sidewalls and bottom surface of the trench 502. The semiconductor layer 701S and 701B may serve to increase the volume of each active region 103. The semiconductor layer 701S and 701B may be selectively formed only in the trench 502 crossing each active region 103. The semiconductor layer 701S and 701B may not be formed over the isolation layer 501. A portion of the semiconductor layer 701S that covers the inner sidewalls of the trench 502 may be a doped region. The semiconductor layer 701B that covers the bottom surface of the trench 502 may serve as a fin or a portion of the fin.

The semiconductor layer 701S and 701B may be formed by an epitaxial growth process. The epitaxial growth process may include a Selective Epitaxial Growth (SEG) process. The semiconductor layer 701S and 701B may be selectively formed on the inner sidewalls and bottom surface of the active region 103 that is exposed by the trench 502.

The semiconductor layer 701S formed on the inner sidewalls of the trench 502 may have a first width W1, and the semiconductor layer 701B formed on the bottom surface of the trench 502 may have a second width W2.

The thickness of the semiconductor layer 701S formed on the inner sidewalls of the trench 502 and the thickness of the semiconductor layer 701B formed on the bottom surface of the trench 502 may be different from each other. In other words, the first width W1 of the semiconductor layer 701S formed on the inner sidewalls of the trench 502 may be larger than the second width W2 of the semiconductor layer 701B formed on the bottom surface of the trench 502.

Referring to FIG. 23B, the height difference between the bottom surface of the trench 502 crossing the isolation layer 501 and the bottom surface of the trench 502 crossing the active region 103 may be the second width W2 of the semiconductor layer 701B on the bottom surface of the trench 502. Therefore, the semiconductor layer 701B on the bottom surface of the trench 502 may function as a fin. The fin may be referred to as a saddle fin. The fin may increase the channel width and improve the electrical characteristics.

The first doped region 114 and the second doped region 115 may be formed in the active region 103. The first doped region 114 may be formed in the active region 103 and the semiconductor layer 701S on one side of the trench 110, and the second doped region 115 may be formed in the active region 103 and the semiconductor layer 701S on the other side of the trench 110. The first doped region 114 may include a first active doped region 103D1 and a first extended doped region 701D1. The second doped region 115 may include a second active doped region 103D2 and a second extended doped region 701D2. The first and second active doped regions 103D1 and 103D2 may refer to an active region 103 that is doped with an impurity. The first and second extended doped regions 701D1 and 701D2 may refer to the semiconductor layer 701S that is doped with an impurity.

According to the embodiment of the present disclosure, the areas of the first and second doped regions 114 and 115 may be increased as much as the widths of the first and second extended doped regions 701D1 and 701D2 by additionally forming the semiconductor layer 701S on both sidewalls of the trench 502. Accordingly, there is an effect of increasing the overlay margin between the substrate 101 and the upper structure (e.g., a bit line BL or a memory element CAP).

The first doped region 114 and the second doped region 115 may be disposed in the active region 103 and the semiconductor layer 701S on both sides of the trench 502. In other words, the first and second doped regions 114 and 115 may be disposed to be spaced apart from each other by the trench 502.

The buried gate structure BG may include a gate dielectric layer 111 that covers the semiconductor layer 701S and 701B formed on the bottom surface and inner sidewalls of the trench 502, a buried conductive layer 112 that fills the lower portion of the trench 110 over the gate dielectric layer 111, and a gate capping layer 113 that fills the upper portion of the trench 110 over the buried conductive layer 112.

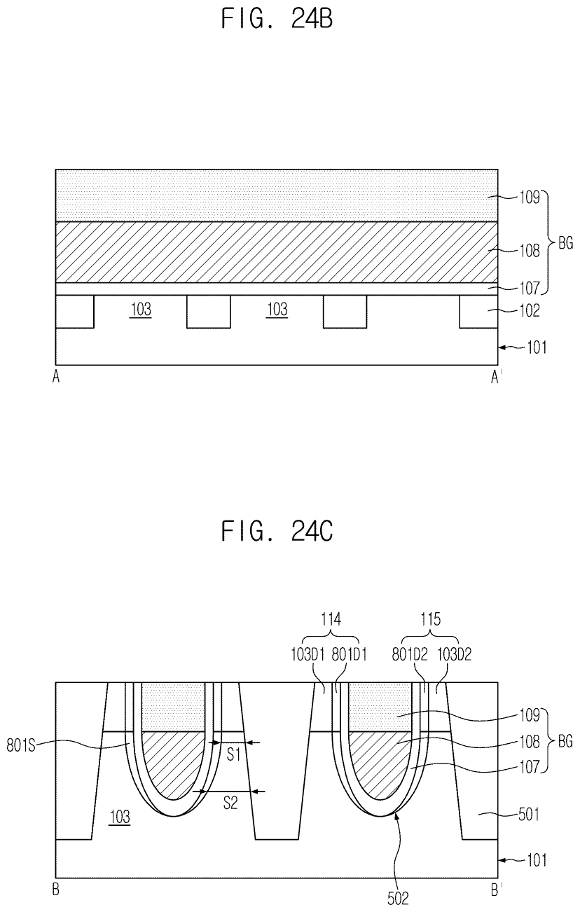

Referring to FIGS. 24A to 24C, the semiconductor device may include a substrate 101, and a buried gate structure BG, a first doped region 114, and a second doped region 115 that are embedded in the substrate 101. The buried gate structure BG and the first and second doped regions 114 and 115 may be a cell transistor. With the buried gate structure, the cell transistor may be able to improve the short channel effect.

A semiconductor layer 801S may be selectively formed only on the inner sidewalls of the trench 502. In other words, the semiconductor layer may not be formed on the bottom surface of the trench 502, and the semiconductor layer 801S may be formed only on the inner sidewalls of the trench 502.

The first doped region 114 and the second doped region 115 may be formed in the active region 103. The first doped region 114 may be formed in the active region 103 and the semiconductor layer 801S on one side of the trench 502, and the second doped region 115 may be formed in the active region 103 and the semiconductor layer 801S on the other side of the trench 502. The first doped region 114 may include a first active doped region 103D1 and a first extended doped region 801D1. The second doped region 115 may include a second active doped region 103D2 and a second extended doped region 801D2. The first and second active doped regions 103D1 and 103D2 may refer to an active region 103 that is doped with an impurity. The first and second extended doped regions 801D1 and 801D2 may refer to the semiconductor layer 801S that is doped with an impurity.

According to the embodiment of the present disclosure, the areas of the first and second doped regions 114 and 115 may be increased as much as the widths of the first and second extended doped regions 801D1 and 801D2 by additionally forming the semiconductor layer 801S on both sidewalls of the trench 502. Therefore, there is an effect that may increase the overlay margin between the substrate 101 and the upper structure (e.g., a bit line BL or a memory element CAP).

The first and second doped regions 114 and 115 may not be disposed on a straight line in the second direction D2. The first and second doped regions 114 and 115 may be disposed to be misaligned on the left and right in the second direction D2 so that there may be no overlapping region.

The first doped region 114 and the second doped region 115 may be disposed in the active region 103 and the semiconductor layer 801S on both sides of the trench 502. In other words, the first and second doped regions 114 and 115 may be disposed to be spaced apart from each other by the trench 502.

The buried gate structure BG may include a gate dielectric layer 111 that covers the semiconductor layer 801S and 801B formed on the bottom surface and inner sidewalls of the trench 502, a buried conductive layer 112 that fills the lower portion of the trench 502 over the gate dielectric layer 111, and a gate capping layer 113 that fills the upper portion of the trench 502 over the buried conductive layer 112.

According to the embodiment of the present disclosure, the upper area of the active area may be increased.

According to the embodiment of the present disclosure, the overlay margin between the upper structure and the lower structure may be increased.

According to the embodiment of the present disclosure, the reliability of a semiconductor device may be secured.

While the present disclosure has been described with respect to the specific embodiments, it will be apparent to those skilled in the art that various changes and modifications may be made without departing from the spirit and scope of the invention as defined in the following claims.

What is claimed is:

1. A semiconductor device comprising:
a substrate including an isolation layer and a plurality of active regions that are defined by the isolation layer;
a trench disposed in the substrate to cross the isolation layer and the plurality of active regions in a first direction;
a semiconductor layer disposed on inner sidewalls and a bottom surface of the trench in each of the plurality of active regions;
a buried gate structure disposed in the trench including the semiconductor layer.

2. The semiconductor device of claim 1, wherein the buried gate structure comprises:
a gate dielectric layer disposed over the trench including the semiconductor layer;
a buried conductive layer disposed in a portion of the trench over the gate dielectric layer;
a gate capping layer disposed in a remaining portion of the trench over the buried conductive layer; and
first and second doped regions disposed in the substrate and separated by the trench.

3. The semiconductor device of claim 2, wherein each of the first and second doped regions includes an active region and a semiconductor layer.

4. The semiconductor device of claim 1, wherein the plurality of active regions are arranged in the first direction and a second direction which is orthogonal to the first direction, and disposed to be tilted in a third direction which is oblique to the first direction and the second direction.

5. The semiconductor device of claim 1, wherein each of the plurality of active regions includes the trench, and the trench is disposed to cross a center of each of the plurality of active regions.

6. The semiconductor device of claim 1, wherein a portion of the semiconductor layer disposed on a first sidewall of the trench does not overlap with another portion of the semiconductor layer disposed on a second sidewall of the trench in the second direction.

7. The semiconductor device of claim 1, wherein the semiconductor layer is SEG(selective epitaxial growth) layer.

8. The semiconductor device of claim 1, wherein the semiconductor layer is disposed to have a same thickness at the inner sidewalls and the bottom surface of the trench.

9. The semiconductor device of claim 1, wherein a thickness of the semiconductor layer on the inner sidewalls of the trench is greater than a thickness of the semiconductor layer on the bottom surface of the trench.

10. The semiconductor device of claim 2, wherein the buried conductive layer has a wavy line shape extending in the first direction.

11. The semiconductor device of claim 1, wherein the isolation layer has a side slope that becomes narrow as the isolation layer extends away from a top surface of the substrate.

12. The semiconductor device of claim 1, wherein the bottom surface of the trench has a curved surface.

13. A semiconductor device comprising:
a substrate including an isolation layer and a plurality of active regions that are defined by the isolation layer;
a trench disposed in the substrate to cross the isolation layer and the plurality of active regions in a first direction;
a semiconductor layer disposed on inner sidewalls of the trench in each of the plurality of active regions;
a gate dielectric layer disposed on the inner sidewalls of the trench including the semiconductor layer; and
a buried conductive layer disposed in a portion of the trench over the gate dielectric layer.

14. The semiconductor device of claim 13, wherein the semiconductor layer has different thicknesses at both sidewalls of the trench.
